(19) United States
(12) Patent Application Publication
(10) Pub. No.: US 2025/0351633 A1
(43) Pub. Date: Nov. 13, 2025

(54) LIGHT-EMITTING DEVICE AND DISPLAY COMPRISING SAME

(71) Applicant: SAMSUNG DISPLAY CO., LTD., Yongin-si (KR)

(72) Inventors: Won Sik OH, Hwaseong-si (KR); Dong Uk KIM, Hwaseong-si (KR); Hyun Min CHO, Seoul (KR)

(21) Appl. No.: 19/273,092

(22) Filed: Jul. 17, 2025

Related U.S. Application Data
(63) Continuation of application No. 17/905,495, filed on Sep. 1, 2022.

(30) Foreign Application Priority Data
Mar. 3, 2020 (KR) 10-2020-0026420

(51) Int. Cl. H10H 20/857; H01L 25/16; H10H 20/819

(52) U.S. Cl. CPC H10H 20/857; H01L 25/167; H10H 20/819

(57) ABSTRACT

A display includes: a first electrode including a first electrode line and a second electrode line; a light-emitting device between the first electrode line and the second electrode line; a first contact electrode including a first pattern overlapping the first electrode line and one end of the light-emitting device and a second pattern overlapping the second electrode line and the other end of the light-emitting device; a second electrode on the light-emitting device and overlapping the first electrode and the light-emitting device; and a second contact electrode between the light-emitting device and the second electrode, wherein a light-emitting device includes a plurality of semiconductor layers and an insulating film partially surrounding the external surfaces of the semiconductor layers, a main body unit, and a light-emitting unit on the main body unit and having a shorter length than the main body unit.

### CROSS-REFERENCE TO RELATED APPLICATIONS

This application is a continuation of U.S. patent application Ser. No. 17/905,495, filed Sep. 1, 2022, which is a U.S. National Phase Patent Application of International Patent Application Number PCT/KR2020/007349, filed on Jun. 5, 2020, which claims priority to and the benefit of Korean Patent Application No. 10-2020-0026420, filed Mar. 3, 2020, the entire content of all of which is incorporated herein by reference.

### BACKGROUND

### 1. Field

The present disclosure relates to a light-emitting device and a display device including the same.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

### SUMMARY

To address the aforementioned problems, embodiments of the present disclosure provide a light-emitting device including a light-emitting part, a body part having a different width from the light-emitting part, and an active layer having a relatively large area.

Embodiments of the present disclosure also provide a display device including the light-emitting device.

It should be noted that aspects and features of embodiments of the present disclosure are not limited thereto and other aspects, which are not mentioned herein, will be apparent to those of ordinary skill in the art from the following description.

According to one or more embodiments of the present disclosure, a display device includes a first electrode including a first electrode line extending in a first direction, and a second electrode line extending in the first direction and spaced from the first electrode line in a second direction. light-emitting devices between the first and second electrode lines. a first contact electrode extending in the first direction and including a first pattern overlapping with the first electrode line and one end portion of each of the light-emitting devices, and a second pattern overlapping with the second electrode line and another end portion of each of the light-emitting devices. A second electrode on the light-emitting devices overlapping at least partially with the first electrode and the light-emitting devices, and a second contact electrode extending in the first direction and located between the light-emitting devices and the second electrode, wherein a light-emitting device of the light-emitting devices includes a plurality of semiconductor layers and an insulating film surrounding parts of outer surfaces of the semiconductor layers, and wherein the light-emitting device further includes a body part extending in the second direction, and a light-emitting part on the body part and having a smaller length than the body parts in the second direction.

The light-emitting devices may include a first light-emitting device including the light-emitting part opposing the second electrode and a second light-emitting device including the light-emitting part facing the first direction.

The body parts of the light-emitting devices may include first and second end portions in the second direction, the first pattern of the first contact electrode may overlap with the first electrode line and the first end portion, and the second pattern of the first contact electrode may overlap with the second electrode line and the second end portion.

A distance between the first and second electrode lines may be less than a length, in the second direction, of the body parts, and the length of the body parts may be less than a distance between the first and second patterns.

The first pattern may be around at least part of the first end portion, and the second pattern may be around at least part of the second end portion, the second pattern being not in contact with the light-emitting parts of the light-emitting devices.

The second contact electrode may be in contact with the light-emitting parts of the light-emitting devices and the second electrode.

A width of the first and second electrode lines may be less than a width of the second electrode.

According to one or more embodiments of the present disclosure, a display device includes a substrate, a first electrode on the substrate and including first and second electrode lines spaced from each other, light-emitting devices between the first and second electrode lines, a first contact electrode including a first pattern on the first electrode line and at least parts of the light-emitting devices, and a second pattern disposed on the second electrode line and at least parts of the light-emitting devices, a second contact electrode on the light-emitting devices, between the first and second patterns, and a second electrode on the second contact electrode, wherein the light-emitting devices include body parts extending in one direction, and light-emitting parts having a smaller length than the body parts in the one direction, the first pattern of the first contact electrode is on first end portions of the body parts, the second pattern of the first contact electrode is on second end portions of the body parts, and the second contact electrode is on the light-emitting parts.

The first pattern of the first contact electrode may be in contact with top surfaces and sides of the first end portions of the light-emitting devices, and the second pattern of the first contact electrode may be in contact with top surfaces and sides of the second end portions of the light-emitting devices.

The second contact electrode may be in contact with top surfaces and sides of the light-emitting parts.

The second contact electrode may be in contact with some parts that are directly connected to the light-emitting parts.

Each of the light-emitting devices may include a plurality of semiconductor layers and an insulating film around parts of outer surfaces of the semiconductor layers, and the insulating film may be around the body parts and sides of the light-emitting parts, wherein the insulating film be not on parts of the body parts where the light-emitting parts are not located, from between sides and top surfaces of the body parts.

The light-emitting devices may include a first light-emitting device including the light-emitting part facing an upward direction of the substrate and a second light-emitting device including the light-emitting part facing a direction parallel to a top surface of the substrate.

Parts of top surfaces and sides of the semiconductor layers of each of the light-emitting devices where the insulating film is not located may be exposed in the first end portions of the light-emitting devices, and a surface of the first light-emitting device that is in contact with the first pattern and top surfaces of the first end portions may be parallel to the top surface of the substrate.

A surface of the second light-emitting device that is in contact with the first pattern and the top surfaces of the first end portions may be perpendicular to the top surface of the substrate.

According to one or more embodiments of the present disclosure, a light-emitting device includes a plurality of semiconductor layers, and an insulating film around parts of outer surfaces of the semiconductor layers, wherein the semiconductor layers include a first semiconductor layer, a second semiconductor layer on the first semiconductor layer, and an active layer between the first and second semiconductor layers, the light-emitting device includes a body part extending in one direction, and a light-emitting part on the body part and having a smaller length than the body part in the one direction, and the active layer is on the light-emitting part.

The light-emitting device may further include a sub-semiconductor layer below the first semiconductor layer, and an electrode layer on the second semiconductor layer.

The first semiconductor layer may include a first portion on the body part, and a second portion protruding from part of a top surface of the first portion, and the active layer may be on the second portion of the first semiconductor layer.

A width of the body part may be same as a width of the light-emitting part, and a sum of heights of the body part and the light-emitting part may be less than a length, in the one direction, of the body part.

The insulating film may be on both surfaces, in a direction of the width, of the body part to be around sides of the light-emitting part and is not on part of a top surface of the body part where the light-emitting part is not located.

The details of other embodiments are included in the detailed description and the accompanying drawings.

According to one or more embodiments of the disclosure, a light-emitting device may include a body part and a light-emitting part having a different length from the body part, and the light-emitting part may protrude from the body part, which extends in one direction. The length, in one direction, of the body part may be greater than the height of the light-emitting device, and as the length of an active layer, which is disposed in the light-emitting part, increases, the active layer may have a relatively large area. The larger the area of the active layer, the higher the emission efficiency of the light-emitting device.

A display device including the light-emitting device may include a first electrode, which is connected to the body part of the light-emitting device, and a second electrode, which is connected to the light-emitting part of the light-emitting device. The display device may include different types of light-emitting devices, which differ from one another in terms of the direction faced by the light-emitting parts of the light-emitting devices, and light generated by active layers of the light-emitting devices can be emitted in various directions.

The effects according to the embodiments are not limited by the contents exemplified above, and more various effects are included in this disclosure.

### BRIEF DESCRIPTION OF THE DRAWINGS

The above and other embodiments and features of the present disclosure will become more apparent by describing embodiments thereof with reference to the attached drawings, in which:

FIG. 1 is a plan view of a display device according to one or more embodiments of the present disclosure;

FIG. 2 is a plan view of a pixel of the display device according to one or more embodiments of the present disclosure;

FIG. 3 is a cross-sectional view taken along the line III-III′ of FIG. 2;

FIG. 4 is a partial cross-sectional view of a display device according to one or more embodiments of the present disclosure;

FIG. 5 is a perspective view of a light-emitting device according to one or more embodiments of the present disclosure;

FIG. 6 is a cross-sectional view of the light-emitting device of FIG. 5;

FIG. 7 is a schematic view illustrating the layout of light-emitting devices on a wafer substrate according to one or more embodiments of the present disclosure;

FIG. 8 is a perspective view illustrating the alignment directions of light-emitting devices according to one or more embodiments of the present disclosure;

FIG. 9 is a cross-sectional view taken along the line VIII-VIII′ of FIG. 2;

FIG. 10 is a cross-sectional view taken along the line IX-IX′ of FIG. 2;

FIG. 11 is a cross-sectional view taken along the line X-X′ of FIG. 2;

FIG. 12 is a cross-sectional view of a light-emitting device according to one or more embodiments of the present disclosure;

FIG. 13 is a cross-sectional view of a display device including the light-emitting device of FIG. 12;

FIG. 14 is a plan view of a subpixel of a display device according to one or more embodiments of the present disclosure;

FIG. 15 is a cross-sectional view taken along the line Q1-Q1′ of FIG. 14;

FIG. 16 is a plan view of a subpixel of a display device according to one or more embodiments of the present disclosure;

FIG. 17 is a cross-sectional view taken along the line Q2-Q2′ of FIG. 16;

FIG. 18 is a plan view of a subpixel of a display device according to one or more embodiments of the present disclosure; and

FIG. 19 is a cross-sectional view taken along the line Q3-Q3′ of FIG. 18.

### DETAILED DESCRIPTION

The present disclosure will now be described more fully hereinafter with reference to the accompanying drawings, in which embodiments of the present disclosure are shown. This disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Hereinafter, embodiments will be described with reference to the accompanying drawings.

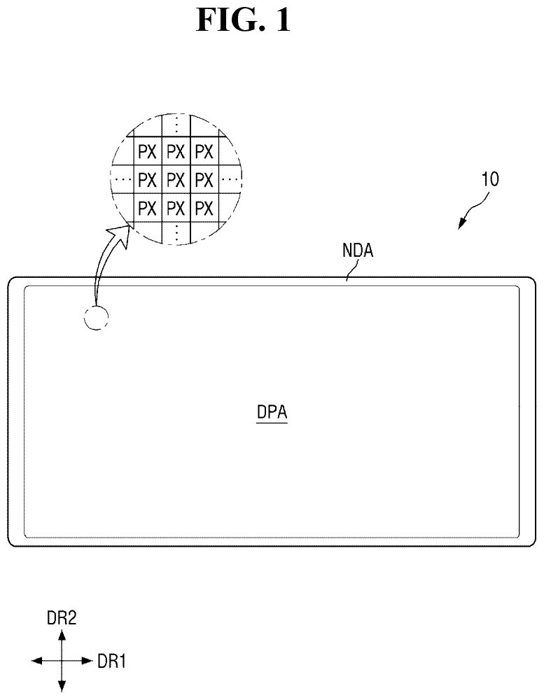

FIG. 1 is a plan view of a display device according to one or more embodiments of the present disclosure.

Referring to FIG. 1, a display device 10 displays a moving or still image. The display device 10 may refer to nearly all types of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book (e-book), a portable multimedia player (PMP), a navigation device, a gaming console, a digital camera, a camcorder, and the like.

The display device 10 includes a display panel that provides a display screen. Examples of the display panel of the display device 10 include an inorganic light-emitting diode (LED) display panel, an organic light-emitting diode (OLED) display panel, a quantum-dot light-emitting diode (QLED) display panel, a plasma display panel (PDP), a field-emission display (FED) panel, and the like. The display panel of the display device 10 will hereinafter be described as being, for example, an ILED display panel, but the present disclosure is not limited thereto. That is, various other display panels are also applicable to the display panel of the display device 10.

The shape of the display device 10 may vary. For example, the display device 10 may have a rectangular shape that extends longer in a horizontal direction than in a vertical direction, a rectangular shape that extends longer in the vertical direction than in the horizontal direction, a square shape, a tetragonal shape with rounded corners, a non-tetragonal polygonal shape, or a circular shape. The shape of a display area DPA of the display device 10 may be similar to the shape of the display device 10. FIG. 1 illustrates that the display device 10 and the display area DPA both have a rectangular shape that extends relatively long in a horizontal direction.

The display device 10 may include the display area DPA and a non-display area NDA around an edge or periphery of the display area DPA. The display area DPA may be an area in which an image is displayed, and the non-display area NDA may be an area in which no image is displayed. The display area DPA may also be referred to as an active area, and the non-display area NDA may also be referred to as an inactive area or a passive area. The display area DPA may occupy the middle or central part of the display device 10.

The display area DPA may include a plurality of pixels PX. The pixels PX may be arranged in row and column directions. Each of the pixels PX may have a rectangular or square shape in a plan view, but the present disclosure is not limited thereto. Alternatively, each of the pixels PX may have a rhombus shape having sides inclined with respect to a particular direction. The pixels PX may be alternately arranged in a stripe or a PENTILE® arrangement structure, but the present disclosure is not limited thereto. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. Each of the pixels PX may include one or more light-emitting devices 300, which emit light of a particular wavelength range.

The non-display area NDA may be disposed around the display area DPA. The non-display area NDA may surround the entire display area DPA or part of the display area DPA. The display area DPA may have a rectangular shape, and the non-display area NDA may be disposed adjacent to four sides of the display area DPA. The non-display area NDA may form the bezel of the display device 10. Lines or circuit drivers included in the display device 10 may be disposed in the non-display area NDA, or external devices may be mounted in the non-display area NDA.

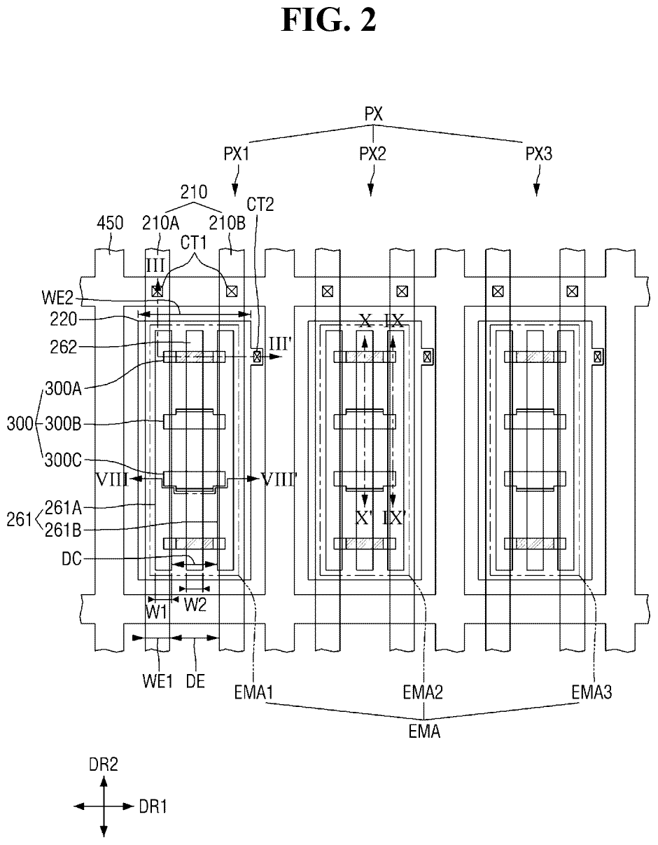

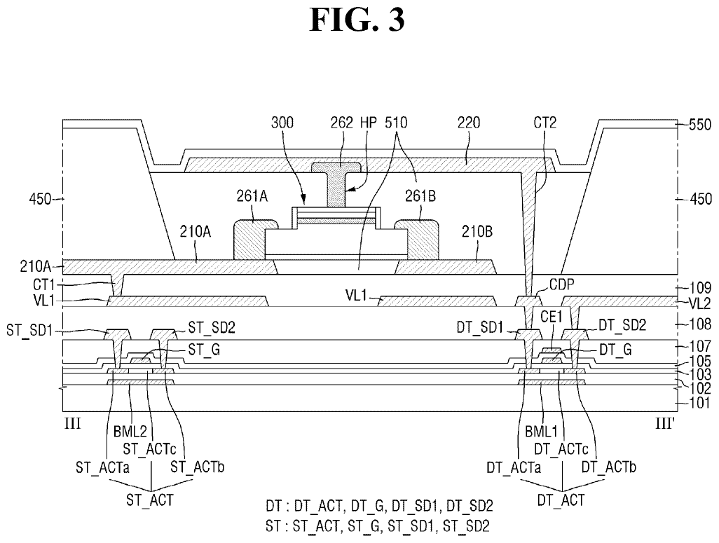

FIG. 2 is a plan view of a pixel of the display device according to one or more embodiments of the present disclosure. FIG. 3 is a cross-sectional view taken along the line III-III′ of FIG. 2.

Referring to FIG. 2, a pixel PX may include first, second, and third subpixels PX1, PX2, and PX3. The first subpixel PX1 may emit first-color light, the second subpixel PX2 may emit second-color light, and the third subpixel PX3 may emit third-color light. The first-color light, the second-color light, and the third-color light may be blue light, green light, and red light, respectively, but the present disclosure is not limited thereto. Alternatively, the subpixels PXn may all emit light of the same color. FIG. 2 illustrates that the pixel PX may include three subpixels PXn, but the present disclosure is not limited thereto. Alternatively, the pixel PX may include more than three subpixels PXn.

The subpixels PXn may include areas defined as emission areas EMA. The first subpixel PX1 may include a first emission area EMA1, the second subpixel PX2 may include a second emission area EMA2, and the third subpixel PX3 may include a third emission area EMA3. Each of the emission areas EMA may be defined as an area where light-emitting devices 300 are disposed to emit light of a particular wavelength band. The light-emitting devices 300 may include active layers, and the active layers may emit light of a particular wavelength band without any directivity.

Light emitted by the active layers of the light-emitting devices 300 may be emitted through both sides of each of the light-emitting devices 300. Each of the emission areas EMA include an area where the light-emitting devices 300 are disposed and may also include an area around the light-emitting devices 300 that outputs light emitted by the light-emitting devices 300.

However, the present disclosure is not limited to this. Each of the emission areas EMA may include an area that outputs light, emitted by the light-emitting devices 300 and then reflected or refracted from other elements. The light-emitting devices 300 may be disposed in each of the subpixels PXn, and the area where the light-emitting devices 300 are disposed and the surrounding areas of the light-emitting devices 300 may form the emission areas EMA.

In one or more embodiments, each of the subpixels PXn of the display device 10 may include a non-emission area, which is defined as an area other than the emission areas EMA. The non-emission area may be an area where the light-emitting devices 300 are not disposed and may not output light because of not being reached by light emitted by the light-emitting devices 300.

FIG. 3 illustrates a cross-sectional view of the first subpixel PX1 of FIG. 2, which, however, may also be directly applicable to other pixels PX or other subpixels PXn. FIG. 3 illustrates a cross-sectional view taken from one end portion to the other end portion of a light-emitting device 300 in the first subpixel PX1 of FIG. 2.

Referring to FIG. 3 and further to FIG. 2, the display device 10 may include a circuit element layer and a display element layer, which are disposed on a first substrate 101. A semiconductor layer, a plurality of conductive layer, and a plurality of insulating layers may be disposed on the first substrate 101 and may form the circuit element layer and the display element layer. The conductive layers may include a first gate conductive layer, a second gate conductive layer, a first data conductive layer, and a second data conductive layer, which are disposed below a first planarization layer 109 and form the circuit element layer, and electrodes (210 and 220) and contact electrodes (261 and 262), which are disposed on the first planarization layer 109 and form the display element layer. The insulating layers may include a buffer layer 102, a first gate insulating layer 103, a first passivation layer 105, a first interlayer insulating layer 107, a second interlayer insulating layer 108, the first planarization layer 109, a first insulating layer 510, and an encapsulation layer 550.

The circuit element layer, which includes circuit elements and a plurality of lines for driving the light-emitting devices 300, may include a driving transistor DT, a switching transistor ST, a first conductive pattern CDP, and a plurality of voltage lines (VL1 and VL2), and the display element layer may include the light-emitting devices 300, a first electrode 210, a second electrode 220, a first contact electrode 261, and a second contact electrode 262.

The first substrate 101 may be an insulating substrate. The first substrate 101 may be formed of an insulating material such as glass, quartz, or a polymer resin. The first substrate 101 may be a rigid substrate or may be a flexible substrate that is bendable, foldable, and/or rollable.

Light-blocking layers (BML1 and BML2) may be disposed on the first substrate 101. The light-blocking layers (BML1 and BML2) may include first and second light-blocking layers BML1 and BML2. The second and first light-blocking layers BML2 and BML1 may be disposed to overlap with at least a second active material layer ST_ACT of the switching transistor ST and a first active material layer DT_ACT of the driving transistor DT, respectively, in a thickness direction of the first substrate 101. The light-blocking layers (BML1 and BML2) may include a material capable of blocking light and may prevent light from being incident upon the first and second active material layers DT_ACT and ST_ACT. For example, the first and second light-blocking layers BML1 and BML2 may be formed of an opaque metal material capable of blocking the transmission of light. However, the present disclosure is not limited to this, and alternatively, the light-blocking layers BML1 and BML2 may not be provided. In one or more embodiments, the first light-blocking layer BML1 may be electrically connected to a first source/drain electrode DT_SD1 of the driving transistor DT, and the second light-blocking layer BML2 may be electrically connected to a first source/drain electrode ST_SD1 of the switching transistor ST.

The buffer layer 102 may include the light-blocking layers (BML1 and BML2) and may be disposed on the entire surface of the first substrate 101. The buffer layer 102 may be formed on the first substrate 101 to protect the driving and switching transistors DT and ST from moisture that may penetrate the first substrate 101, which is susceptible to moisture, and may perform a surface planarization function. The buffer layer 102 may include a plurality of inorganic layers that are alternately stacked. For example, the buffer layer 102 may be formed as a multilayer in which inorganic layers including at least one of silicon oxide (SiOₓ), silicon nitride (SiNₓ), and silicon oxynitride (SiON) are alternately stacked. The semiconductor layer is disposed on the buffer layer 102. The

semiconductor layer may include the first active material layer DT_ACT of the driving transistor DT and the second active material layer ST_ACT of the switching transistor ST. The first active material layer DT_ACT of the driving transistor DT and the second active material layer ST_ACT of the switching transistor ST may be disposed to partially overlap with gate electrodes (DT_G and ST_G) of the first gate conductive layer in a thickness direction of the first substrate 101.

In one or more embodiments, the semiconductor layer may include polycrystalline silicon, monocrystalline silicon, or an oxide semiconductor. Here, the polycrystalline silicon may be formed by crystallizing amorphous silicon by, for example, rapid thermal annealing (RTA), solid phase crystallization (SPC), excimer laser annealing (ELA), metal induced crystallization (MILC), or sequential lateral solidification (SLS), but the present disclosure is not limited thereto. In a case where the semiconductor layer includes polycrystalline silicon, the first active material layer DT_ACT may include a first doped region DT_ACTa, a second doped region DT_ACTb, and a first channel region DT_ACTc. The first channel region DT_ACTc may be disposed between the first and second doped regions DT_ACTa and

DT_ACTb. The second active material layer ST_ACT may include a third doped region ST_ACTa, a fourth doped region ST_ACTb, and a second channel region ST_ACTc. The second channel region ST_ACTc may be disposed between the third and fourth doped regions ST_ACTa and ST_ACTb. The first, second, third, and fourth doped regions DT_ACTa, DT_ACTb, ST_ACTa, and ST_ACTb may be parts of the first or second active material layer DT_ACT or ST_ACT that are doped with impurities.

In one or more embodiments, the first and second active material layers DT_ACT and ST_ACT may include an oxide semiconductor. In this case, the doped regions of each of the first and second active material layers DT_ACT and ST_ACT may be conductor regions. The oxide semiconductor may be an oxide semiconductor containing indium (In). In some embodiments, the oxide semiconductor may be indium-tin oxide (ITO), indium-zinc oxide (IZO), indium-gallium oxide (IGO), indium-zinc-tin oxide (IZTO), indium-gallium-tin oxide (IGTO), or indium-gallium-zinc-tin oxide (IGZTO), but the disclosure is not limited thereto.

The first gate insulating layer 103 is disposed on the semiconductor layer and the buffer layer 102. The first gate insulating layer 103 may be disposed on the buffer layer 102, including the semiconductor layer. The first gate insulating layer 103 may function as a gate insulating film for the driving transistor DT and the switching transistor ST. The first gate insulating layer 103 may be formed as an inorganic layer including an inorganic material such as, for example, SiOₓ, SiNₓ, or SiON or as a stack of such inorganic materials.

The first gate conductive layer is disposed on the first gate insulating layer 103. The first gate conductive layer may include a first gate electrode DT_G of the driving transistor DT and a second gate electrode ST_G of the switching transistor ST. The first gate electrode DT_G may be disposed to overlap with at least a part of the first active material layer DT_ACT in a thickness direction of the first substrate 101, and the second gate electrode ST_G may be disposed to overlap with at least a part of the second active material layer ST_ACT in a thickness direction of the first substrate 101. For example, the first gate electrode DT_G may be disposed to overlap with the first channel region DT_ACTc of the first active material layer DT_ACT in a thickness direction, and the second gate electrode ST_G may be disposed to overlap with the second channel region ST_ACTc of the second active material layer ST_ACT in the thickness direction.

The first gate conductive layer may be formed as a single layer or a multilayer including one of molybdenum (Mo), aluminum (AI), chromium (Cr), gold (Au), titanium (Ti), nickel (Ni), neodymium (Nd), copper (Cu), and an alloy thereof, but the present disclosure is not limited thereto.

The first passivation layer 105 is disposed on the first gate conductive layer and the first gate insulating layer 103. The first passivation layer 105 may be disposed to cover and protect the first gate conductive layer. The first passivation layer 105 may be formed as an inorganic layer including an inorganic material such as, for example, SiOₓ, SiNₓ, or SiON or as a stack of such inorganic materials.

The second gate conductive layer is disposed on the first passivation layer 105. The second gate conductive layer may include a first capacitance electrode CE1 of a storage capacitor, which is disposed to overlap at least partially with the first gate electrode DT_G in the thickness direction. The first capacitance electrode CE1 may overlap with the first gate electrode DT_G in the thickness direction with the first passivation layer 105 interposed therebetween, and the storage capacitor may be formed between the first capacitance electrode CE1 and the first gate electrode DT_G. However, the present disclosure is not limited to this. Alternatively, the first capacitance electrode CE1 of the storage capacitor may be disposed not to overlap with the first gate electrode DT_G in the thickness direction.

The second gate conductive layer may be formed as a single layer or a multilayer including one of Mo, Al, Cr, Au, Ti, Ni, Nd, Cu, and an alloy thereof, but the present disclosure is not limited thereto.

The first interlayer insulating layer 107 is disposed on the second gate conductive layer. The first interlayer insulating layer 107 may function as an insulating film between the second gate conductive layer and layers disposed on the second gate conductive layer and the first passivation layer 105. The first interlayer insulating layer 107 may be formed as an inorganic layer including an inorganic material such as, for example, SiOₓ, SiNₓ, or SiON or as a stack of such inorganic materials.

The first data conductive layer is disposed on the first interlayer insulating layer 107. The first data conductive layer may include the first source/drain electrode DT_SD1 and a second source/drain electrode DT_SD2 of the driving transistor DT and the first source/drain electrode ST_SD1 and a second source/drain electrode ST_SD2 of the switching transistor ST.

The first source/drain electrode DT_SD1 and the second source/drain electrode DT_SD2 of the driving transistor DT may be in contact with the first and second doped regions DT_ACTa and DT_ACTb of the first active material layer DT_ACT through contact holes penetrating the first interlayer insulating layer 107, the first passivation layer 105, and the first gate insulating layer 103. The first source/drain electrode ST_SD1 and the second source/drain electrode ST_SD2 of the switching transistor ST may be in contact with the third and fourth doped regions ST_ACTa and ST_ACTb of the second active material layer ST_ACT through contact holes penetrating the first interlayer insulating layer 107, the first passivation layer 105, and the first gate insulating layer 103. The first source/drain electrode DT_SD1 of the driving transistor DT and the first source/drain electrode ST_SD1 of the switching transistor ST may be electrically connected to the first and second light-blocking layers BML1 and BML2, respectively, through other contact holes. If one of the first and second source/drain electrodes DT_SD1 and DT_SD2 of the driving transistor DT or one of the first and second source/drain electrodes ST_SD1 and ST_SD2 of the switching transistor ST is a source electrode, the other source/drain electrode may be a drain electrode, but the present disclosure is not limited thereto. Alternatively, if one of the first and second source/drain electrodes DT_SD1 and DT_SD2 of the driving transistor DT or one of the first and second source/drain electrodes ST_SD1 and ST_SD2 of the switching transistor ST is a drain electrode, the other source/drain electrode may be a source electrode.

The first data conductive layer may be formed as a single layer or a multilayer including one of Mo, Al, Cr, Au, Ti, Ni, Nd, Cu, and an alloy thereof, but the present disclosure is not limited thereto.

The second interlayer insulating layer 108 is disposed on the first data conductive layer and the first interlayer insulating layer 107. The second interlayer insulating layer 108 may be disposed on the entire surface of the first interlayer insulating layer 107, covering the first data conductive layer, and may protect the first data conductive layer. The second interlayer insulating layer 108 may be formed as an inorganic layer including an inorganic material such as, for example, SiOₓ, SiNₓ, or SiON or as a stack of such inorganic materials.

The second data conductive layer is disposed on the second interlayer insulating layer 108. The second data conductive layer may include first voltage lines VL1, a second voltage line VL2, and the first conductive pattern CDP. A low-potential voltage (or a first power supply voltage VSS), which is to be supplied to the first electrode 210, may be applied to the first voltage lines VL1, and a high-potential voltage (or a second power supply voltage VDD), which is to be supplied to the driving transistor DT, may be applied to the second voltage line VL2. An alignment signal for aligning the light-emitting devices 300 may be applied to the first voltage lines VL1 during the fabrication of the display device 10.

The first conductive pattern CDP may be electrically connected to the first source/drain electrode DT_SD1 of the driving transistor DT through a contact hole formed in the second interlayer insulating layer 108. The first conductive pattern CDP may be in contact with the second electrode 220 that will be described later, and the driving transistor DT may transmit the second power supply voltage VDD from the second voltage line VL2 to the second electrode 220 through the first conductive pattern CDP. The second data conductive layer is illustrated as including two first voltage lines VL1 and one second voltage line VL2, but the present disclosure is not limited thereto. Alternatively, the second data conductive layer may include more than two first voltage lines VL1 and more than one second voltage line VL2.

The second data conductive layer may be formed as a single layer or a multilayer including one of Mo, Al, Cr, Au, Ti, Ni, Nd, Cu, and an alloy thereof, but the present disclosure is not limited thereto.

The first planarization layer 109 is disposed on the second data conductive layer and the second interlayer insulating layer 108. The first planarization layer 109 may include an organic insulating material, particularly, an organic material such as, for example, polyimide (PI), and may perform a surface planarization function.

A plurality of electrodes (210 and 220), an outer bank 450, a plurality of contact electrodes (261 and 262), and the light-emitting devices 300 are disposed on the first planarization layer 109.

The first electrode 210 may be disposed in each of the subpixels PXn, extending in a second direction DR2. The first electrode 210 may be disposed to extend into subpixels PXn that are adjacent to one another in the second direction DR2. That is, first electrodes 210 that are connected to one another may be disposed in subpixels PXn that are adjacent to one another in the second direction DR2. The first electrodes 210 may form linear patterns on the entire surface of the display area DPA of the display device 10.

The display device 10 may include a first electrode 210, which is disposed in each of the subpixels PXn. For example, the first electrode 210 may include first and second electrode lines 210A and 210B. The first and second electrode lines 210A and 210B may extend in the second direction DR2 and may be spaced from each other in a first direction DR1. A plurality of light-emitting devices 300 may be disposed between the first and second electrode lines 210A and 210B, and the first and second electrode lines 210A and 210B may be electrically connected to both end portions of each of the light-emitting devices 300. The same electrical signals may be applied to the first and second electrode lines 210A and 210B, and the first and second electrode lines 210A and 210B may form the first electrode 210.

The first electrode 210 may be disposed directly on the first planarization layer 109. The first and second electrode lines 210A and 210B of the first electrode 210 may be disposed on the first planarization layer 109 to be spaced from, and oppose, each other, and the light-emitting devices 300 may be disposed between the first and second electrode lines 210A and 210B. As will be described later, the light-emitting devices 300 may be disposed between the first and second electrode lines 210A and 210B to be placed at least in part on the first and second electrode lines 210A and 210B. The first and second electrode lines 210A and 210B may be electrically connected to first end portions of the light-emitting devices 300.

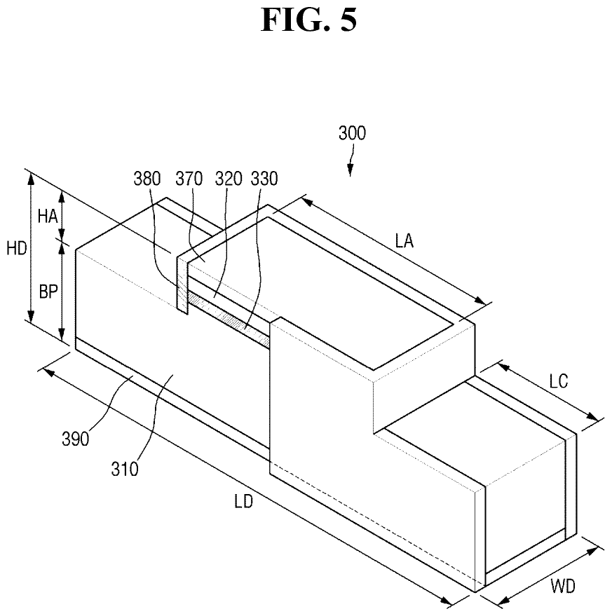

A width WE1 of the first and second electrode lines 210A and 210B and a distance DE between the first and second electrode lines 210A and 210B are not particularly limited. However, in some embodiments, the distance DE between the first and second electrode lines 210A and 210B may be less than the length (“LD” of FIG. 5) of the light-emitting devices 300 and greater than the distance (“DC” of FIG. 2) between the first contact electrodes 261 (e.g., 261A, 261B). The first and second electrode lines 210A and 210B may be electrically connected to the first end portions of the light-emitting devices 300 through the first contact electrode 261. As the first and second electrode lines 210A and 210B are disposed to be spaced from each other by as much as the distance DE, the first and second electrode lines 210A and 210B may be electrically connected to the first end portions of the light-emitting devices 300. This will be described later.

The first electrode 210 may partially overlap with the outer bank 450, along the boundaries between subpixels PXn that are adjacent to one another in the second direction DR2, and may be electrically connected to the first voltage lines VL1 in areas overlapping with the outer bank 450. For example, the first electrode 210 may be formed in the areas overlapping with the outer bank 450 and may be in contact with the first voltage lines VL1 through first contact holes CT1, which penetrate the first planarization layer 109. First electrodes 210 of subpixels PXn that are adjacent to one another in the first direction DR1 may be electrically connected to first voltage lines VL1 through first contact holes CT1, and the same electrical signals applied to the first voltage lines VL1 may be transmitted to the subpixels PXn through the first electrodes 210, which extend in the second direction DR2.

The second electrode 220 is disposed on the first electrode 210. For example, the second electrode 220 may be disposed to overlap at least partially with the first electrode 210 in the thickness direction. The second electrode 220 may be disposed to correspond to each of the subpixels PXn. The second electrode 220 may be disposed in each of the subpixels PXn, and one second electrode 220 may not be connected to, but may be spaced from, second electrodes 220 of other subpixels PXn.

As a result, second electrodes 220 may be disposed on the entire surface of the display device 10 as island patterns. As will be described later, a plurality of light-emitting devices 300, the first contact electrode 261, the second contact electrode 262, and the first insulating layer 510 may be disposed between the second electrode 220 and the first electrode 210 of each of the subpixels PXn.

The second electrode 220 may have an angular shape including one side extending in one direction and another side extending in another direction, in a plan view, but the present disclosure is not limited thereto. Alternatively, the second electrode 220 may have an inclined shape with respect to one direction or a circular shape with a curved outer surface. The size of the second electrode 220 is not particularly limited, but may vary depending on the area of each of the subpixels PXn of the display device 10. The second electrode 220 may be formed to be smaller than each of the subpixels PXn and may be disposed to be spaced from the boundaries between neighboring pixels PXn.

In one or more embodiments, the second electrode 220 may have a width or area different from electrode lines (210A and 210B) of the first electrode 210. For example, a width WE2, in the first direction DR1, of the second electrode 220 may be greater than the width WE1 of the electrode lines (210A and 210B). Also, the width WE2 of the second electrode 220 may be greater than the sum of the width WE1 of the first and second electrode lines 210A and 210B and the distance DE between the first and second electrode lines 210A and 210B. Accordingly, the second electrode 220 may cover both sides, in the first direction DR1, of each of the first and second electrode lines 210A and 210B, but the present disclosure is not limited thereto.

The second electrode 220 may be disposed to be spaced from the first electrode 210, in a direction perpendicular to the top surface of the first substrate 101. For example, the second electrode 220 may be spaced from the first electrode 210 in the thickness direction and may be disposed directly on the first insulating layer 510, which is disposed between the first and second electrodes 210 and 220. A plurality of light-emitting devices 300 may be disposed between the first and second electrodes 210 and 220, and the spaces between the first and second electrodes 210 and 220 may be filled with the first insulating layer 510. The second electrode 220 may be electrically connected to at least one end portion of each of the light-emitting devices 300. For example, the second electrode 220 may be electrically connected to second end portions of the light-emitting devices 300 through the second contact electrode 262, but the present disclosure is not limited thereto.

The second electrode 220 may be electrically connected to the driving transistor DT. For example, the second electrode 220 may be in contact with the first conductive pattern CDP through a second contact hole CT2, which exposes part of the top surface of the first conductive pattern CDP through the first insulating layer 510 and the first planarization layer 109. The second electrode 220 may be electrically connected to the first source/drain electrode DT_SD1 of the driving transistor DT through the first conductive pattern CDP and may receive the second power supply voltage VDD, which is applied through the second voltage line VL2. The second electrode 220 may be electrically connected to different driving transistors DT, which are disposed in different subpixels PXn, and may receive the second power supply voltage VDD independently from each of the different driving transistors DT.

Each of the subpixels PXn is illustrated as including one first electrode 210, which includes a pair of electrode lines (210A and 210B), and one second electrode 220, but the present disclosure is not limited thereto. Alternatively, in one or more embodiments, more than one first electrode 210 and more than second electrode 220 may be disposed in each of the subpixels PXn. The shapes of the first and second electrodes 210 and 220, which are disposed in each of the subpixels PXn, are not particularly limited, and the first and second electrodes 210 and 220 may be arranged in various layouts. For example, the first and second electrodes 210 and 220 may be partially curved or bent, and one of the first and second electrodes 210 and 220 may be disposed to be around (e.g., to surround) the other electrode. At least parts of the first and second electrodes 210 and 220 may be spaced from, and oppose, each other, and the structures and shapes of the first and second electrodes 210 and 220 are not particularly limited, if an area in which to arrange the light-emitting devices 300 is formed.

The electrodes (210 and 220) may be electrically connected to the light-emitting devices 300, and suitable voltages (e.g., predetermined voltages) may be applied to the electrodes (210 and 220) such that the light-emitting devices 300 may emit light. For example, the electrodes (210 and 220) may be electrically connected to the light-emitting devices 300, and electrical signals applied to the electrodes (210 and 220) may be transmitted to the light-emitting devices 300 through the contact electrodes (261 and 262).

In one or more embodiments, the first electrode 210 may be connected in common throughout multiple subpixels PXn, and the second electrode 220 may be separated between the multiple subpixels PXn. However, the present disclosure is not limited to this. Alternatively, the first electrode 210 may be separated between the multiple pixels PXn, and the second electrode 220 may be connected in common throughout the multiple pixels PXn. One of the first and second electrodes 210 and 220 may be electrically connected to the anodes of the light-emitting devices 300, and the other electrode may be electrically connected to the cathodes of the light-emitting devices 300. However, the present disclosure is not limited to this.

The first and second electrodes 210 and 220 may be used to form an electric field in each of the subpixels PXn to align the light-emitting devices 300. The light-emitting devices 300 may be disposed between the first and second electrode lines 210A and 210B by applying alignment signals to the first and second electrode lines 210A and 210B of the first electrode 210 to form an electric field between the first and second electrode lines 210A and 210B. The light-emitting devices 300 may be sprayed onto the first electrode 210 in a state of being dispersed in ink through inkjet printing. In response to an alignment signal being applied between the first and second electrode lines 210A and 210B, the light-emitting devices 300 may receive a dielectrophoretic force and may thus be aligned between the first and second electrode lines 210A and 210B of the first electrode 210.

The electrodes (210 and 220) may include a transparent conductive material. For example, the electrodes (210 and 220) may include a material such as ITO, IZO, or ITZO, but the present disclosure is not limited thereto. The light-emitting devices 300 may emit light in the directions of both end portions thereof, particularly, in a direction facing the top surface of the first electrode 210. In one or more embodiments, the first electrode 210 may include a conductive material with high reflectance and may thus be able to reflect light traveling toward the top surface of the first electrode 210 after being emitted by the light-emitting devices 300. The second electrode 220 may include a transparent material and may thus transmit some of the light emitted by the light-emitting devices 300 therethrough, in each of the subpixels PXn. In one or more embodiments, the first electrode 210 may include a material with high reflectance such as silver (Ag), copper (Cu), or Al.

However, the present disclosure is not limited to this. Alternatively, the first electrode 210 may have a stack of one or more layers of a transparent conductive material and one or more layers of a metal with high reflectance or may be formed as a single layer including the transparent conductive material and the metal with high reflectance. In one or more embodiments, the first electrode 210 may have a stack of ITO/Ag/ITO/IZO or may include an alloy of Al, Ni, or lanthanum (La).

The outer bank 450 may be disposed on the first planarization layer 109. As illustrated in FIGS. 2 and 3, the outer bank 450 may be disposed along the boundaries between the subpixels PXn. The outer bank 450 may be disposed to extend at least in the second direction DR2 and to surround not only the area where the light-emitting devices 300 are disposed, between the electrode lines (210A and 210B), but also at least some of the light-emitting devices 300. The outer bank 450 may further include parts extending in the first direction DR1 and may thus form a lattice pattern over the entire surface of the display area DPA.

The height of the outer bank 450 may be greater than the height of the first insulating layer 510 in the thickness direction. Also, the height of the top surface of the outer bank 450 may be greater than the height of the top surface of the second electrode 220 in the thickness direction. The outer bank 450 may separate neighboring subpixels PXn from one another and may prevent ink from spilling over between the neighboring subpixels PXn in an inkjet printing process for arranging the light-emitting devices 300 during the fabrication of the display device 10. That is, the outer bank 450 may separate ink having different sets of light-emitting devices 300 for different subpixels PXn dispersed therein, not to be mixed together. The outer bank 450 may include polyimide (PI), but the present disclosure is not limited thereto.

Not only the light-emitting devices 300, but also the first contact electrode 261, the second contact electrode 262, and the first insulating layer 510 may be disposed between the first and second electrodes 210 and 220.

The light-emitting devices 300 may be disposed in each of the subpixels PXn, between the first and second electrode lines 210A and 210B. The light-emitting devices 300 may also be disposed between the first and second electrodes 210 and 220. First ends of the light-emitting devices 300 may be electrically connected to the first electrode 210, and second ends of the light-emitting devices 300 may be electrically connected to the second electrode 220.

The light-emitting devices 300 may be spaced from one another and may be aligned substantially in parallel to one another. The distance between the light-emitting devices 300 is not particularly limited. Some of the light-emitting devices 300 may be disposed adjacent to one another to form a group, and some of the light-emitting devices 300 may be disposed a suitable distance (e.g., a predetermined distance) from one another to form another group. Alternatively, the light-emitting devices 300 may be aligned in one direction with a nonuniform density. Also, in one or more embodiments, the light-emitting devices 300 may extend in one direction, and the direction in which the first electrode 210 extends may form a substantially right angle with the direction in which the light-emitting devices 300 extend. However, the present disclosure is not limited to this. Alternatively, the light-emitting devices 300 may extend diagonally with respect to the direction in which the first electrode 210 extends.

The light-emitting devices 300 may be disposed between the first and second electrode lines 210A and 210B. For example, in one or more embodiments, the first end portions of the light-emitting devices 300 may be disposed on the first electrode line 210A, and the second end portions of the light-emitting devices 300 may be disposed on the second electrode line 210B. Both end portions of each of the light-emitting devices 300 may be disposed to overlap with the first and second electrode lines 210A and 210B in the thickness direction. As described above, the length (“LD” of FIG. 5), in one direction, of the light-emitting devices 300 may be greater than the distance DE between the first and second electrode lines 210A and 210B. The first and second end portions of each of the light-emitting devices 300 may be in direct contact with the first and second electrode lines 210A and 210B, respectively, but the present disclosure is not limited thereto. Alternatively, in one or more embodiments, an insulating layer may be further disposed to cover the first electrode, and the light-emitting devices 300 may be disposed directly on the insulating layer.

In each of the light-emitting devices 300, a plurality of layers may be disposed along a direction perpendicular to the top surface of the first substrate 101 or the first planarization layer 109. The light-emitting devices 300 may extend in one direction, and a plurality of semiconductor layers may be sequentially arranged in one direction in each of the light-emitting devices 300. The light-emitting devices 300 may be disposed such that the direction in which the light-emitting devices 300 extend may be parallel to the first planarization layer 109, and the plurality of semiconductor layers included in each of the light-emitting devices 300 may be sequentially arranged along a direction perpendicular to the top surface of the first planarization layer 109, and may each extend in parallel to the top surface of the first planarization layer 109. However, the present disclosure is not limited to this. Alternatively, in a case where the light-emitting devices 300 have a different structure, a plurality of layers may be disposed in each of the light-emitting devices 300, in a direction perpendicular to the first planarization layer 109.

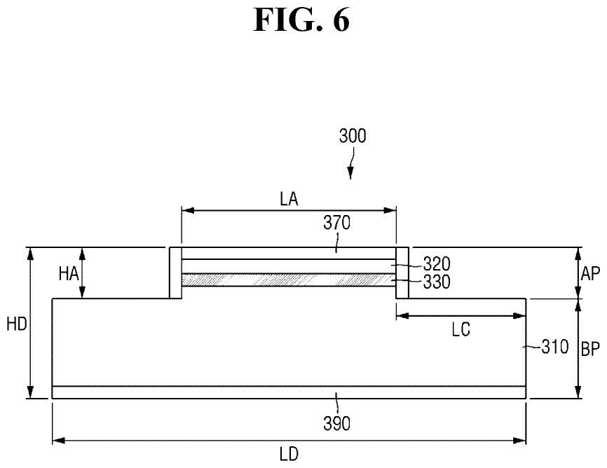

As will be described later, each of the light-emitting devices 300 may include a body part (“BP” of FIG. 5), which has a large length, and a light-emitting part (“AP” of FIG. 6), which is formed on the body part BP and in which an active layer (“330” of FIG. 5) is disposed. The light-emitting devices 300 may protrude in part from the body parts BP thereof, and the body parts BP of the light-emitting devices 300 may protrude from both sides of the light-emitting parts AP of the light-emitting devices 300. Each of the light-emitting devices 300 may include a first end portion, a second end portion, and a third end portion where a light-emitting part AP is disposed.

The body parts BP of the light-emitting devices 300 may be disposed on the first and second electrode lines 210A and 210B, and the light-emitting parts AP of the light-emitting devices 300 may be disposed to face one direction with respect to the body parts BP. For example, the first end portions of the light-emitting devices 300 may be disposed on the first electrode line 210A, and the second end portions of the light-emitting devices 300 may be disposed on the second electrode line 210B. Also, the light-emitting devices 300 may be disposed such that the light-emitting parts AP of the light-emitting devices 300 may face the direction in which the first electrode 210 extends, i.e., the second direction DR2, or may oppose the top surface of the first substrate 101. The light-emitting devise 300 may include different types of light-emitting devices 300 depending on the direction faced by the light-emitting parts AP of the light-emitting devices 300. For example, the light-emitting devices 300 may include a first light-emitting device 300A whose light-emitting part AP faces an upward direction of the first substrate 101 and second and third light-emitting devices 300B and 300C whose light-emitting parts AP face the second direction DR2.

As will be described later, each of the light-emitting parts AP of the light-emitting devices 300 may include an active layer 330, and the active layer 330 may emit light of a particular wavelength band in response to an electrical signal being transmitted thereto. As the display device 10 includes light-emitting devices (300A, 300B, and 300C), which differ from one another in the alignment direction of the light-emitting parts AP thereof, the display device 10 can emit light not only in the upward direction of the first substrate 101, but also in lateral directions.

In one or more embodiments, the body parts BP of the light-emitting devices 300 may be in direct contact with the first electrode 210. As illustrated in FIG. 3, the light-emitting devices 300 may be disposed on the first electrode 210, and the first and second end portions of the body parts BP of the light-emitting devices BP may be in direct contact with the first and second electrode lines 210A and 210B, respectively. The light-emitting device 300 of FIG. 3 is the first light-emitting device 300A whose light-emitting part AP is disposed to face the upward direction of the first substrate 101. The bottom surfaces of the first and second end portions of the body part BP of the first light-emitting device 300A may be in direct contact with the first and second electrode lines 210A and 210B, respectively, but the present disclosure is not limited thereto.

As will be described later, the light-emitting parts AP of the second and third light-emitting devices 300B and 300C may be disposed to face the second direction DR2, and sides of the first and second end portions of each of the second and third light-emitting devices 300B and 300C may be disposed to be in contact with the first electrode 210. This will be described later.

The light-emitting devices 300 may include active layers 330 including different materials and may thus emit light of different wavelength bands to the outside. The display device 10 may include light-emitting devices 300 capable of emitting light of different wavelength bands. The light-emitting devices 300 of the first subpixel PX1 may include active layers 330 emitting first-color light having a first wavelength as a central wavelength, the light-emitting devices 300 of the second subpixel PX2 may include active layers 330 emitting second-color light having a second wavelength as a central wavelength, and the light-emitting devices 300 of the third subpixel PX3 may include active layers 330 emitting third-color light having a third wavelength as a central wavelength.

Accordingly, the first subpixel PX1 may emit the first-color light, the second subpixel PX2 may emit the second-color light, and the third subpixel PX3 may emit the third-color light. In one or more embodiments, the first-color light may be blue light having a central wavelength of 450 nm to 495 nm, the second-color light may be green light having a central wavelength of 495 nm to 570 nm, and the third-color light may be red light having a central wavelength of 620 nm to 752 nm. However, the present disclosure is not limited to this. Alternatively, the first, second, and third subpixels PX1, PX2, and PX3 may include light-emitting devices 300 of the same type and may thus all emit light of the same color.

The first insulating layer 510 may be disposed between the first and second electrodes 210 and 220 to be around (e.g., to surround) the outer surfaces of each of the light-emitting devices 300. For example, the first insulating layer 510 may be disposed on the first planarization layer 109 to cover the first electrode 210 and may be in direct contact with the first planarization layer 109 and the first electrode 210. The first insulating layer 510 may prevent the first electrode 210 from being in direct contact with the second electrode 220 and may insulate the first and second electrodes 210 and 220 from each other. Also, as will be described later, the first insulating layer 510 may insulate the first and second contact electrodes 261 from each other.

The first insulating layer 510 may be disposed on the first planarization layer 109 and may form a pattern in each of the subpixels PXn or in some subpixels PXn. In one or more embodiments, the first insulating layer 510 may form island or linear shapes on the entire surface of the display device 10. The first insulating layer 510 may be disposed to be around (e.g., to

surround) the outer surfaces (e.g., the outer peripheral or circumferential surfaces) of each of the light-emitting devices 300, which are disposed on the first electrode 210. The first insulating layer 510 may be thick enough to cover the light-emitting devices 300, which are disposed on the first electrode 210. In one or more embodiments, the thickness of the first insulating layer 510 may be greater than at least the height (“HD” of FIG. 5) of the light-emitting devices 300 and the thickness of the first electrode 210 in the thickness direction. The first insulating layer 510 may compensate for height differences formed by the first electrode 210 and the light-emitting devices 300, which are disposed on the first planarization layer 109. A hole HP, which exposes at least parts of the outer surfaces (e.g., the outer peripheral or circumferential surfaces) of each of the light-emitting devices 300, may be formed in the first insulating layer 510, and the second contact electrode 262 that will be described later may be disposed in the hole HP. At least one end portion of each of the light-emitting devices 300 may be exposed by the hole HP in the first insulating layer 510, and exposed parts of the light-emitting devices 300 may be in contact with the second contact electrode 262. A second contact hole CT2, which penetrates the first insulating layer 510, may be formed in the first insulating layer 510 and the first planarization layer 109, and the second electrode 220 may be electrically connected to the driving transistor DT through the second contact hole CT2.

In one or more embodiments, the first insulating layer 510 may be disposed even in the spaces between the first electrode line 210A, the second electrode line 210B, and the light-emitting devices 300. Both end portions of each of the light-emitting devices 300 may be disposed on the first and second electrode lines 210A and 210B, and spaces may be formed between the light-emitting devices 300 and the first and second electrode lines 210A and 210B. The material of the first insulating layer 510 may fill the spaces during the fabrication of the display device 10.

The first and second end portions of each of the light-emitting devices 300 may be disposed on the first and second electrode lines 210A and 210B. The display device 10 may include the first contact electrode 261 (e.g., 261A, 261B), which is disposed on the first and second electrode lines 210A and 210B, and the first and second end portions of each of the light-emitting devices 300 may be in contact with the first contact electrode 261 (e.g., 261A, 261B). Also, the display device 10 may include the second contact electrode 262, which is disposed between the light-emitting devices 300 and the second electrode 220, and the third end portions of the light-emitting devices 300 may be in contact with the second contact electrode 262.

The first contact electrode 261 may extend in one direction on the first electrode 210. The first contact electrode 261 may include first and second patterns 261A and 261B, and the first and second patterns 261A and 261B may be disposed on the first and second electrode lines 210A and 210B, respectively. The first and second patterns 261A and 261B, like the first electrode 210, may be disposed to extend in the second direction DR2 and may be spaced from each other in the first direction DR1. The first contact electrode 261 may form linear patterns in each of the subpixels PXn.

The first and second patterns 261A and 261B may be disposed at least in part on, and in direct contact with, the first and second electrode lines 210A and 210B, respectively, but the present disclosure is not limited thereto. In one or more embodiments, another insulating layer may be further disposed on the first electrode 210, and the first contact electrode 261 may be disposed on the insulating layer. In this case, the first contact electrode 261 may be in direct contact with the first electrode 210 through an opening exposing part of the top surface of the first electrode 210 through the insulating layer.

The first contact electrode 261 may be in direct contact with parts of the light-emitting devices 300, for example, the first and second end portions of each of the light-emitting devices 300. The first pattern 261A of the first contact electrode 261 may be in contact with the first end portions of the light-emitting devices 300, and the second pattern 261B of the first contact electrode 261 may be in contact with the second end portions of the light-emitting devices 300. In one or more embodiments, the first and second patterns 261A and 261B may be in contact with the top surfaces and sides of the first and second end portions of each of the light-emitting devices 300, but may be spaced from protruding parts of the light-emitting devices 300, i.e., the third end portions of the light-emitting devices 300. FIG. 3 illustrates that the first and second patterns 261A and 261B are in contact with the top surfaces and sides of the first and second end portions, respectively, of each of the light-emitting devices 300, but the present disclosure is not limited thereto. The first and second patterns 261A and 261B may extend in the second direction DR2 on the first electrode 210 and may thus be disposed even in the gaps between the light-emitting devices 300 to be around (e.g., to surround) the first and second end portions of each of the light-emitting devices 300. As will be described later, the semiconductor layers of each of the light-emitting devices 300 may be partially exposed in the first and second end portions of each of the light-emitting devices 300, and the first and second patterns 261A and 261B may be in direct contact with the semiconductor layers of each of the light-emitting devices 300. As the semiconductor layers of each of the light-emitting devices 300 are in direct contact with the first contact electrode 261, the light-emitting devices 300 may be electrically connected to the first electrode 210.

A width W1 of the first and second patterns 261A and 261B of the first contact electrode 261 may be less than a width WE1 of the first and second electrode lines 210A and 210B. As the first and second patterns 261A and 261B are disposed on the first and second electrode lines 210A and 210B, respectively, and are formed to have a smaller width W1 than the first and second electrode lines 210A and 210B, parts of the top surfaces of the first and second electrode lines 210A and 210B may be exposed, but the present disclosure is not limited thereto. In one or more embodiments, the width W1 of the first and second patterns 216A and 216B may be greater than the width WE1 of the first and second electrode lines 210A and 210B, and the first contact electrode 261 may be disposed to cover the top surface of the first electrode 210.

A distance DC between the first and second patterns 261A and 261B may be less than the distance DE between the first and second electrode lines 210A and 210B. The distance DC between the first and second patterns 261A and 261B may vary depending on the length of the light-emitting devices 300 and the lengths of the first and second end portions of each of the light-emitting devices 300. As described above, the distance DE between the first and second electrode lines 210A and 210B may be less than the length of the light-emitting devices 300 such that both end portions of each of the light-emitting devices 300 may be placed on the electrode lines (210A and 210B). On the contrary, the distance DC between the first and second patterns 261A and 261B may be controlled to cover both end portions of each of the light-emitting devices 300. In one or more embodiments, the distance DC between the first and second patterns 261A and 261B may be less than the distance DE between the electrode lines (210A and 210B), and the first and second patterns 261A and 261B may be disposed to be around (e.g., surround) parts of the first and second end portions of each of the light-emitting devices 300.

The second contact electrode 262 may be disposed between the first and second patterns 261A and 261B, in a plan view, and may extend in the second direction DR2. That is, the second contact electrode 262 may be arranged substantially in the same layout as the first contact electrode 261 and may be disposed in each of the subpixels PXn to form linear patterns.

The second contact electrode 262 may be disposed between the light-

emitting devices 300 and the second electrode 220. In one or more embodiments, the second contact electrode 262 may be in contact with the third end portions of the light-emitting devices 300 or the light-emitting parts (“AP” of FIG. 5) of the light-emitting devices 300. The second contact electrode 262 may be formed in the first insulating layer 510 to be disposed in the hole HP, which exposes parts of the third end portions of the light-emitting devices 300. The third end portions of the light-emitting devices 300 may be partially exposed by the hole HP, and the second contact electrode 262 may be disposed in the hole HP to be in direct contact with the third end portions of the light-emitting devices 300. The semiconductor layers of each of the light-emitting devices 300 may be partially exposed in the third end portions of the light-emitting devices 300, and the second contact electrode 262 may be in direct contact with the semiconductor layers of each of the light-emitting devices 300. As the semiconductor layers of each of the light-emitting devices 300 are in direct contact with the second contact electrode 262, the light-emitting devices 300 may be electrically connected to the second electrode 220. The second electrode 220 may be disposed to cover the second contact electrode 262, on the first insulating layer 510.

FIG. 3 illustrates that the second contact electrode 262 is in direct contact with the top surfaces of the third end portions of the light-emitting devices 300, but the present disclosure is not limited thereto. The hole HP, which is formed in the first insulating layer 510, may expose not only parts of the third end portions of the light-emitting devices 300, but also first and second surfaces of the light-emitting devices 300, and the second contact electrode 262 may be disposed to be around (e.g., to surround) substantially the middle parts of the light-emitting devices 300. This will be described later.

In one embodiment, a width W2 of the second contact electrode 262 may be the same as the width W1 of the first and second patterns 261A and 261B of the first contact electrode 261. The width W2 of the second contact electrode 262 may be less than the width WE2 of the second electrode 220, and the second electrode 220 may entirely cover the second contact electrode 262. However, the present disclosure is not limited to this, and the width W2 of the second contact electrode 262 may vary. For example, the second contact electrode 262 may be formed to be longer than the third end portions of the light-emitting devices 300 and may thus be in contact with larger areas of the third end portions of the light-emitting devices 300.

The contact electrodes (261 and 262) may include a conductive material. For example, the contact electrodes (261 and 262) may include ITO, IZO, ITZO, or Al. For example, the contact electrodes (261 and 262) may include a transparent conductive material, and light emitted from the light-emitting devices 300 may travel toward the electrodes (210 and 220) through the contact electrodes (261 and 262). As the first electrode 210 includes a material with high reflectance, light incident upon the first electrode 210 may be reflected toward the upper direction of the first substrate 101. On the contrary, as the second electrode 220 includes a transparent material, light incident upon the second electrode 220 may pass through the second electrode 220. However, the present disclosure is not limited to this.

The encapsulation layer 550 may be disposed on the entire surface of the first substrate 101. The encapsulation layer 550 may protect the elements disposed on the first substrate 101 from an external environment.

The first insulating layer 510 and the encapsulation layer 550 may include an inorganic insulating material or an organic insulating material. In one or more embodiments, the first insulating layer 510 and the encapsulation layer 550 may include an inorganic insulating material such as SiOₓ, SiNₓ, SiOₓN_{y}, aluminum oxide (Al₂O₃), or aluminum nitride (AlN). In one or more embodiments, the first insulating layer 510 and the encapsulation layer 550 may include an organic insulating material such as an acrylic resin, an epoxy resin, a phenolic resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, or a polymethyl methacrylate-polycarbonate synthetic resin. However, the present disclosure is not limited to these embodiments.

FIG. 3 illustrates that the first insulating layer 510 has a flat top surface regardless of any underlying height differences, but the present disclosure is not limited thereto. The first insulating layer 510 may include an inorganic insulating material, may have a uniform thickness, and may have a curved top surface depending on the height differences formed by the elements disposed therebelow.

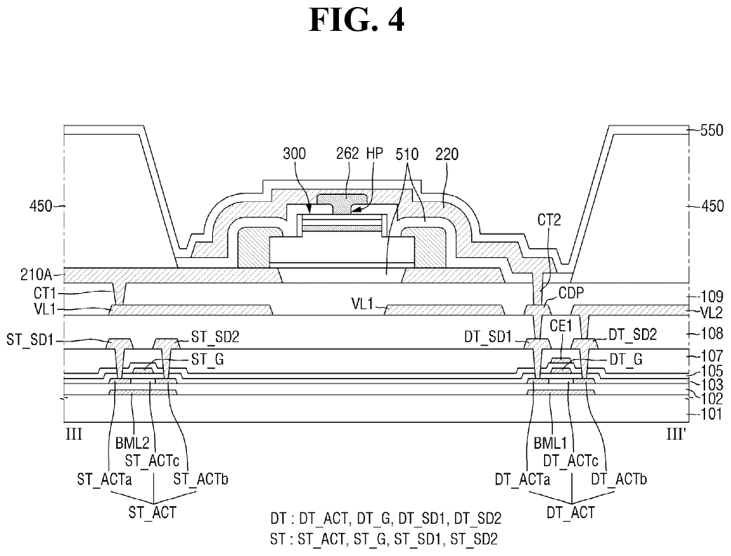

FIG. 4 is a partial cross-sectional view of a display device according to one or more embodiments of the present disclosure.

Referring to FIG. 4, in a display device 10, a first insulating layer 510 may have a uniform thickness and may be disposed to cover a first electrode 210, a first contact electrode 261 (261A and 261B), and light-emitting devices 300. The first insulating layer 510 may be deposited in each subpixel PXn to cover the first electrode 210, the first contact electrode 261 (261A and 261B), and the light-emitting devices 300 and may be stepped, conforming to the shapes of the first electrode 210, the first contact electrode 261 (261A and 261B), and the light-emitting devices 300. Accordingly, a second electrode 220, which is disposed on the first insulating layer 510, may be curved along the top surface of the first insulating layer 510.

The first insulating layer 510 may be deposited to cover not only the light-emitting devices 300, but also the first contact electrode 261 (261A and 261B) and the first electrode 210 and may then be patterned to expose parts of the tops of the light-emitting devices 300. The second contact electrode 262 may be disposed in a patterned part of the first insulating layer 510 and may be electrically connected to the light-emitting devices 300. The embodiment of FIG. 4 is the same as the embodiment of FIG. 3 except for the above-mentioned features, and thus, a detailed description thereof will be omitted.

The display device 10 may include a plurality of subpixels PXn and pixels PX where a plurality of light-emitting devices 300 are disposed and may thus be able to emit light of a particular wavelength band in each area thereof. The light-emitting devices 300 may emit light of different colors and may thus display different colors in each of the subpixels PXn, but the present disclosure is not limited thereto. The light-emitting devices 300 in each of the subpixels PXn may emit light of the same color, and in one or more embodiments, the display device 10 may further include a color conversion substrate, which is disposed to be spaced from, and face (e.g., oppose), a first substrate 101 and converts the color of light emitted by the light-emitting devices 300. In one or more embodiments, the color conversion substrate may include a plurality of color control layers and a color mixing preventing member, and the color control layers may be disposed to correspond to the subpixels PXn of the display device 10. Light emitted by the light-emitting devices 300 may be incident upon the color control layers, and the color control layers may include light conversion layers, which convert the wavelength of the incident light, and light-transmitting layers, which transmit the incident light therethrough while maintaining the wavelength of the incident light. The wavelength conversion layers or the light-transmitting layers may be disposed to be separated between the subpixels PXn, and the color mixing preventing member may be disposed along the boundaries between the wavelength conversion layers or the light-transmitting layers.

In one or more embodiments, the wavelength conversion layers may be disposed in subpixels PXn where the wavelength of light incident from the light-emitting devices 300 does not need to be changed because it differs from the color of the subpixels PXn. The light-emitting layers may be disposed in subpixels PXn, the color of which is the same as the wavelength of light incident from the light-emitting devices 300. However, the present disclosure is not limited to this. Only the wavelength conversion layers, but not the light-transmitting layers, may be disposed in subpixels PXn where the light-emitting devices 300 emit light of a different wavelength from the color of the subpixels PXn, such as ultraviolet light. Alternatively, only the light-transmitting layers, but not the wavelength conversion layers, may be disposed in subpixels PXn where the light-emitting devices 300 emit light of the same color as the subpixels PXn.

Each of the wavelength conversion layers may include a wavelength conversion material and a base resin, in which the wavelength conversion material is dispersed. Each of the light-transmitting layers may include a scatterer and a base resin, in which the scatterer is dispersed.

The base resins may include a light-transmitting organic material. For example, the base resins may include an epoxy resin, an acrylic resin, a cardo resin, or an imide resin. The base resins may be formed of the same material for all the wavelength conversion layers or for all the light-transmitting layers, but the present disclosure is not limited thereto.

The scatterer may be particles of a metal oxide or particles of an organic material. Examples of the metal oxide include titanium oxide (TiO₂), zirconium oxide (ZrO₂), aluminum oxide (Al₂O₃), indium oxide (In₂O₃), zinc oxide (ZnO), or tin oxide (SnO₂), and the organic material may be an acrylic resin or a urethane resin.

The wavelength conversion material may be quantum dots, quantum rods, phosphors, or the like. The quantum dots may include Group IV nanocrystals, Group II-VI compound nanocrystals, Group III-V compound nanocrystals, Group IV-VI nanocrystals, or a combination thereof. However, the present disclosure is not limited thereto.

The color mixing preventing member may include an organic material. The color mixing preventing member may include a light-absorbing material capable of absorbing a visible light wavelength band. In one or more embodiments, the color mixing preventing member may include an organic light-blocking material.

The color conversion substrate may include a separate substrate, may be disposed to be spaced from, and face (e.g., oppose), the first substrate 101 where the light-emitting devices 300 are disposed, and may be coupled to the first substrate 101 via a sealing member, but the present disclosure is not limited thereto. In one or more embodiments, the wavelength conversion layers and the light-transmitting layers of the color conversion substrate may be formed directly on the subpixels PXn where the light-emitting devices 300 are disposed, without a separate substrate. In this case, the wavelength conversion layers and the light-transmitting layers may be disposed directly on an encapsulation layer 550, and the color mixing preventing member may be disposed on an outer bank 450.

The light-emitting devices 300 may be light-emitting diodes (LEDs), particularly, inorganic LEDs having a size of several micrometers or nanometers and formed of an inorganic material. The inorganic LEDs may be aligned between two opposing electrodes where polarity is formed in response to an electric field being formed therebetween. The light-emitting devices 300 may be aligned between the two opposing electrodes by the electric field.

Each of the light-emitting devices 300 may include a plurality of semiconductor layers and an insulating film partially surrounding the semiconductor layers. The semiconductor layers of each of the light-emitting devices 300 may include semiconductor layers doped with impurities of an arbitrary conductivity type (e.g., a p type or an n type). The semiconductor layers may receive electrical signals applied thereto from an external source and may thereby emit light of a particular wavelength band.

FIG. 5 is a perspective view of a light-emitting device according to one or more embodiments of the present disclosure. FIG. 6 is a cross-sectional view of the light-emitting device of FIG. 5. FIG. 5 illustrates a plurality of semiconductor layers of a light-emitting device 300 with part of an insulating film 380 removed therefrom, and FIG. 6 is a cross-sectional view taken along the direction in which the light-emitting device 300 extends.

Referring to FIGS. 5 and 6, the light-emitting device 300 may include a plurality of semiconductor layers and the insulating film 380, which partially surrounds the outer surfaces (e.g., the outer peripheral or circumferential surfaces) of the semiconductor layers. The light-emitting device 300 may extend at least in part in one direction and may include a part extending in a direction perpendicular to the direction in which the semiconductor layers are stacked. For example, the light-emitting device 300 may include a body part BP, which extends in one direction, and a light-emitting part AP, which is formed on the body part BP. As will be described later, the light-emitting part AP, which is part of the light-emitting device 300 where an active layer 330 is disposed, may be part of the light-emitting device 300 that emits light in response to an electrical signal being received.

The body part BP and the light-emitting part AP of the light-emitting device 300 may have different lengths in one direction. A length LD of the body part BP may be greater than a length LA of the light-emitting part AP. The light-emitting part AP may be formed on one surface of the body part BP and may protrude from the surface of the body part BP. Part of the surface of the body part BP may be exposed because of the absence of the light-emitting part AP thereon, and the semiconductor layers may be directly exposed on the exposed part of the surface of the body part BP. As described above, the light-emitting device 300 may include first and second end portions, which are both end portions of the body part BP, and a third end portion where the light-emitting part AP is disposed. The first and second end portions of the light-emitting device 300 may be both end portions of the body part BP that are exposed due to the absence of the light-emitting part AP. The third end portion, which protrudes beyond the body part BP, may be an end portion of the light-emitting device 300 where the light-emitting part AP is disposed.

The body part BP, the light-emitting part AP, and the first, second, and third end portions may be simply for defining parts of the light-emitting device 300 or parts of semiconductor layers of the light-emitting device 300, and may be integrally formed together to form the light-emitting device 300, rather than being formed to be separate from one another. That is, the body part BP, the light-emitting part AP, and the first, second, and third end portions may refer to parts of the light-emitting devices 300. However, the body part BP, the light-emitting part AP, and the first, second, and third end portions are not necessarily limited to parts of the light-emitting device 300 including a plurality of semiconductor layers, but may be understood as referring to parts of the elements of the light-emitting device 300, for example, parts of the first semiconductor layer 310, the active layer 330, and the second semiconductor layer 320.

The light-emitting device 300 may include a plurality of semiconductor layers, and the end portions of the light-emitting device 300 may be in direct contact with a first or second contact electrode 261 and 262 that has been described above. The first, second, and third end portions of the light-emitting device 300 may include parts where the insulating film 380 is not disposed and the semiconductor layers are exposed. The exposed semiconductor layers may be in direct contact with the first or second contact electrode 261 or 262.

The body part BP and the light-emitting part AP of the light-emitting device 300 may have the same width, i.e., a width WD. As a result, first and second surfaces of the light-emitting device 300 may be flat without having any protrusions thereon. The length LD of the body part BP of the light-emitting device 300 may be greater than the length LA of the light-emitting part AP, but a length LC of the first and second end portions of the body part BP may be less than the length LA of the light-emitting part AP. As the light-emitting part AP has the length LA and the width WD, the active layer 330 can have a relatively large area, and the emission efficiency of the light-emitting device 300 can be improved. The length LD of the body part BP of the light-emitting device 300 may be greater than the height HD of the light-emitting device 300.

In one or more embodiments, the length LD of the body part BP of the light-emitting device 300 may be 3 μm to 10 μm or 5 μm to 8 μm, preferably about 7 μm. The height HD of the light-emitting device 300 may be 0.1 μm to 5 μm or 0.3 μm to 2 μm, preferably 0.5 μm to 1 μm. A height HA of the light-emitting part AP may be 100 nm to 500 nm, and the width WD of the light-emitting device 300 may be 300 nm to 700 nm. However, the present disclosure is not limited to this, and the width WD of the light-emitting device 300 of the display device 10 and the height HA of the light-emitting part AP may vary depending on the composition of the active layer 330. Preferably, the width WD of the light-emitting device 300 may be about 500 nm, and the height HA of the light-emitting part AP may be about 150 nm.

Each of the sides of the light-emitting device 300 are illustrated as extending in one direction, and the corners where the sides of the light-emitting device 300 meet are illustrated as being angled. That is, part of the light-emitting device 300 may have a polygonal prism shape, such as a cube, a cuboid, or a hexagonal prism shape, but the present disclosure is not limited thereto. Alternatively, the light-emitting device 300 may have a curved shape such as a rod, a wire, or a tube shape. The corners where the sides of the light-emitting device 300 meet will hereinafter be described as being angled, as illustrated in FIGS. 4 and 5.

The semiconductor layers of the light-emitting device 300 may include the first semiconductor layer 310, the second semiconductor layer 320, and the active layer 330. The light-emitting device 300 may further include a sub-semiconductor layer 390, which is disposed below the first semiconductor layer 310, and an electrode layer 370, which is disposed on the second semiconductor layer 320. The first semiconductor layer 310 and the sub-semiconductor layer 390 of the light-emitting device 300 may be disposed in the body part BP of the light-emitting device 300, and part of the first semiconductor layer 310, the active layer 330, the second semiconductor layer 320, and the electrode layer 370 may be disposed in the light-emitting part AP of the light-emitting device 300. The insulating film 380 may be around (e.g., may surround) the outer surfaces (e.g., the outer peripheral or circumferential surfaces) of the semiconductor layers of the light-emitting device 300, but may be disposed to expose parts of the semiconductor layers of the light-emitting device 300. The light-emitting device 300 is illustrated as including both the sub-semiconductor layer 390 and the electrode layer 370, but the present disclosure is not limited thereto. Alternatively, at least one of the sub-semiconductor layer 390 and the electrode layer 370 may not be provided.

In one or more embodiments, the sub-semiconductor layer 390 may be a semiconductor not doped with impurities. For example, the sub-semiconductor layer 390 may include the same semiconductor material as the first semiconductor layer 310, but may be a semiconductor layer not doped with an n- or p-type dopant. In one or more embodiments, the sub-semiconductor layer 390 may include a semiconductor material, i.e., AlₓGa_{y}In_{1-x-y}N (where 0≤x≤1,0sy≤1, and 0≤x+y≤1), and may be, for example, at least one of AlGaInN, GaN, AlGaN, InGaN, AlN, and InN that are not doped. The sub-semiconductor layer 390 may have a thickness of 0.01 μm to 0.1 μm, but the present disclosure is not limited thereto. In one or more embodiments, the sub-semiconductor layer 390 may be provided.

The first semiconductor layer 310 may be disposed on the sub-semiconductor layer 390. The first semiconductor layer 310 may be an n-type semiconductor. For example, in a case where the light-emitting device 300 emits blue-wavelength light, the first semiconductor layer 310 may include a semiconductor material, i.e., AlxGayIn1-x-yN (where 0≤x≤1,0≤y≤1, and 0≤x+y≤1). For example, the first semiconductor layer 310 may include at least one of AlGaInN, GaN, AlGaN, InGaN, AlN, and InN that are doped with an n-type dopant. The first semiconductor layer 310 may be doped with an n-type dopant, and the n-type dopant may be, for example, Si, Ge, or Sn. For example, the first semiconductor layer 310 may be n-GaN doped with n-type Si. The first semiconductor layer 310 may have a thickness of 0.3 μm to 0.75 μm, but the present disclosure is not limited thereto.

The first semiconductor layer 310 may include a first portion corresponding to the body part BP of the light-emitting device 300 and a second portion corresponding to the light-emitting part of the light-emitting device 300. The second portion may be formed on part of the first portion and may protrude from part of the top surface of the first portion. The length LD of the first portion of the first semiconductor layer 310 may be greater than the length LA of the second portion of the first semiconductor layer 310. The sub-semiconductor layer 390 may be disposed on, and in direct contact with, the bottom surface of the first portion of the first semiconductor layer 310, and the active layer 330, the second semiconductor layer 320, and the electrode layer 370 may be sequentially disposed on the second portion of the first semiconductor layer 310. However, the present disclosure is not limited to this.

The second semiconductor layer 320 may be disposed in the light-emitting part AP of the light-emitting device 300. The second semiconductor layer 320 may be disposed on the second part of the first semiconductor layer 310 and may be disposed on the first semiconductor layer 310 with the active layer 330 interposed therebetween.

The second semiconductor layer 320 may be a p-type semiconductor. In a case where the light-emitting device 300 emits blue- or green-wavelength light, the second semiconductor layer 320 may include a semiconductor material, i.e., AlxGayIn1-x-yN (where 0≤x≤1,0≤y≤1, and 0≤x+y≤1). For example, the second semiconductor layer 320 may include at least one of AlGaInN, GaN, AlGaN, InGaN, AlN, and InN that are doped with a p-type dopant. The second semiconductor layer 320 may be doped with a p-type dopant, and the p-type dopant may be, for example, Mg, Zn, Ca, Se, or Ba. In one or more embodiments, the second semiconductor layer 320 may be p-GaN doped with p-type Mg. The second semiconductor layer 320 may have a thickness of 0.05 μm to 0.10 μm, but the present disclosure is not limited thereto.

The first and second semiconductor layers 310 and 320 are illustrated as being formed as single layers, but the present disclosure is not limited thereto. Alternatively, in one or more embodiments, each of the first and second semiconductor layers 310 and 320 may include more than one layer such as, for example, a clad layer or a tensile strain barrier reducing (TSBR) layer, depending on the material of the active layer 330.

The active layer 330 is disposed between the first and second semiconductor layers 310 and 320. The active layer 330 may be disposed on the second part of the first semiconductor layer 310, between the first and second semiconductor layers 310 and 320, in the light-emitting part AP. The active layer 330 may include a quantum layer and may thus be able to emit light of a particular wavelength band. The wavelength of light emitted by the active layer 330 may vary depending on the content of the material of the quantum layer. The content of the material of the quantum layer may vary depending on the lattice constant of the first semiconductor layer 310 where the active layer 330 is disposed. The lattice constant of the first semiconductor layer 310 may vary depending on the material, the diameter, or the shape of the first semiconductor layer 310.

The active layer 330 may include a single or multi-quantum well structure material. In a case where the active layer 330 includes a material having a multi-quantum well structure, the active layer 330 may have a structure in which multiple quantum layers and multiple well layers are alternately stacked. The active layer 330 may emit light by combining electron-hole pairs in accordance with electrical signals applied thereto via the first and second semiconductor layers 310 and 320. For example, in a case where the active layer 330 emits blue-wavelength light, the quantum layers may include a material such as AlGaN or AlGaInN. For example, in a case where the active layer 330 has a multi-quantum well structure in which multiple quantum layers and multiple well layers are alternately stacked, the quantum layers may include a material such as AlGaN or AlGaInN, and the well layers may include a material such as GaN or AlInN. In one or more embodiments, in a case where the active layer 330 includes AlGaInN as its quantum layer(s) and AlInN as its well layer(s), the active layer 330 can emit blue light having a central wavelength range of 450 nm to 495 nm.

However, the present disclosure is not limited to this. Alternatively, the active layer 330 may have a structure in which a semiconductor material having a large band gap energy and a semiconductor material having a small band gap energy are alternately stacked or may include Group-III or Group-V semiconductor materials depending on the wavelength of light to be emitted. The type of light emitted by the active layer 330 is not particularly limited. The active layer 330 may emit light of a red or green wavelength range as necessary, instead of blue light. The active layer 330 may have a thickness of 0.05 μm to 0.10 μm, but the present disclosure is not limited thereto.

Light may be emitted not only from the outer surface (e.g., the outer peripheral or circumferential surface), in the direction of the height HD, of the light-emitting device 300, but also from both sides of the light-emitting device 300. The directionality of the light emitted from the active layer 330 is not particularly limited.

The electrode layer 370 may be an ohmic contact electrode, but the present disclosure is not limited thereto. Alternatively, the electrode layer 370 may be a Schottky contact electrode. The light-emitting device 300 may include at least one electrode layer 370. FIGS. 5 and 6 illustrate that the light-emitting device 300 includes one electrode layer 370, but the present disclosure is not limited thereto. Alternatively, the light-emitting device 300 may include more than one electrode layer 370, or the electrode layer 370 may not be provided. However, the following description of the light-emitting device 300 may also be directly applicable to a light-emitting device 300 having more than one electrode layer 370 or having a different structure from the light-emitting device 300 of FIGS. 5 and 6.

The electrode layer 370 may be disposed on the second semiconductor layer 320. For example, the electrode layer 370 may be disposed directly on the second semiconductor layer 320. The electrode layer 370 may have substantially the same shape as the second semiconductor layer 320.

The electrode layer 370 may reduce the resistance between the light-emitting device 300 and a second electrode 220 (or a second contact electrode 262) when the light-emitting device 300 is electrically connected to the second electrode 220 (or the second contact electrode 262). The electrode layer 370 may include a conductive metal. For example, the electrode layer 370 may include at least one of Al, Ti, In, Au, Ag, ITO, IZO, and ITZO. Also, the electrode layer 370 may include a semiconductor material doped with an n- or p-type dopant. Electrode layers 370 may include the same materials or different materials, but the present disclosure is not limited to this.

The insulating film 380 may be disposed to be around (e.g., to surround) parts of the semiconductor layers of the light-emitting device 300. The insulating film 380 may protect the semiconductor layers of the light-emitting device 300, particularly, the active layer 330. As described above, the light-emitting device 300 may be electrically connected to first and second electrodes 210 and 220, and the outer surfaces (e.g., the outer peripheral or circumferential surfaces) of the light-emitting device 300 may be in direct contact with other layers, for example, a first insulating layer 510 and contact electrodes (261 and 262).

The insulating film 380 may be disposed to expose at least parts of the outer surfaces (e.g., the outer peripheral or circumferential surfaces) of the semiconductor layers of the light-emitting device 300. For example, the insulating film 380 may be disposed on both surfaces, in the direction of the width WD, of the body part BP. As described above, as the body part BP and the light-emitting part AP have the same width, i.e., the width WD, the insulating film 380 may form a flat surface on each of the first and second surfaces of the light-emitting device 300. The insulating film 380 may be disposed to be around (e.g., to surround) the sides of the semiconductor layers corresponding to the light-emitting part AP of the light-emitting device 300, but may expose the top surface of the light-emitting part AP, for example, the top surface of the electrode layer 370 or the second semiconductor layer 320. However, the insulating film 380 may not be disposed on the top surface and the sides of each of the first and second end portions of the body part BP. Parts of the top surface and the sides of the first portion of the first semiconductor layer 310 corresponding to the body part BP may be exposed.

Accordingly, the semiconductor layers of the light-emitting device 300 may be exposed in parts of the light-emitting device 300 where the insulating film 380 is not disposed, i.e., on the bottom surface of the body part BP, parts of the top surface and sides of each of the first and second end portions of the body part BP, and the top surface of the light-emitting part AP. The exposed semiconductor layers of the light-emitting device 300 may be in direct contact with electrodes (210 and 220) or the contact electrodes (261 and 262) of the display device 10 and may thus receive electrical signals from the electrodes (210 and 220) or the contact electrodes (261 and 262). For example, the first semiconductor layer 310 exposed in the first and second end portions of the light-emitting device 300 may be in contact with the first contact electrode 261, and the electrode layer 370 exposed in the light-emitting part AP of the light-emitting device 300, i.e., in the third end portion of the light-emitting device 300, may be in contact with the second contact electrode 262. However, the present disclosure is not limited to this example.

The insulating film 380 may have a thickness of 10 nm to 1.0 μm, but the present disclosure is not limited thereto. In one or more embodiments, the insulating film 380 may have a thickness of about 40 nm.

The insulating film 380 may include a material with insulating properties such as, for example, SiOₓ, SiNₓ, SiOₓN_{y}, AlN, Al₂O₃, or an organic insulating material. The insulating film 380 can prevent any short circuit that may occur when the active layer 330 is placed in direct contact with electrodes that transmit electrical signals directly to the light-emitting device 300. Also, because the insulating film 380 protects the outer surface (e.g., the outer peripheral or circumferential surface) of the light-emitting device 300 that includes the active layer 330, any degradation in the emission efficiency of the light-emitting device 300 can be prevented.

Also, in one or more embodiments, the outer surface (e.g., the outer peripheral or circumferential surface) of the insulating film 380 may be subjected to surface treatment. The light-emitting device 300 may be sprayed on electrodes while being scattered in ink (e.g., predetermined ink) during the fabrication of the display device 10. Here, the surface of the insulating film 380 may be hydrophobically or hydrophilically treated to keep the light-emitting device 300 scattered in ink without agglomerating with other light-emitting devices 300. However, the present disclosure is not limited to this.

The light-emitting device 300 may be fabricated by an epitaxial growth method, which grows crystals for forming the above-described semiconductor layers on a wafer substrate. As the light-emitting device 300 includes the body part BP and the light-emitting part AP and has angular corners where sides meet, the area of the active layer 330 per unit area of a wafer substrate may increase. That is, the efficiency of the fabrication of the light-emitting device 300 can be improved.

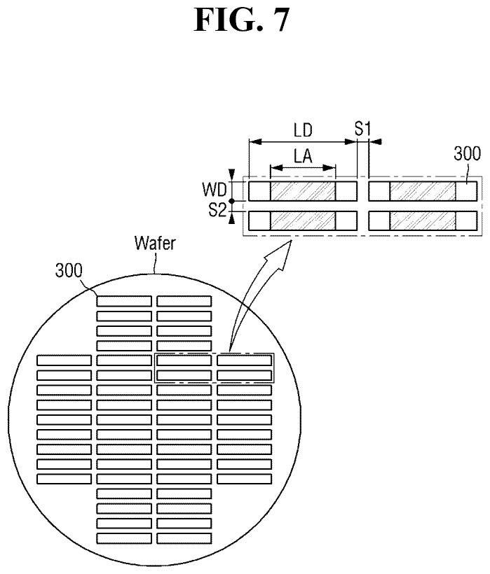

FIG. 7 is a schematic view illustrating the layout of light-emitting devices on a wafer substrate according to one or more embodiments of the present disclosure.

Referring to FIG. 7, light-emitting devices 300 may be fabricated on a wafer substrate to be at a suitable distance (e.g., a predetermined distance) from one another. The light-emitting devices 300 may have the width WD and the length LD, and the length LA of light-emitting parts AP of the light-emitting devices 300 may be determined. The length LA and the width WD of the light-emitting parts AP may be the same as the length and the width of active layers 330 of the light-emitting devices 300. Once the distances (“S1” and S2″ of FIG. 7) between the light-emitting devices 300 are determined, the area of the active layers 330 of the light-emitting devices 330 per unit area may be represented by Equation 1.

(LA*WD)/[(LD+S1)*(WD+S2)] [Equation 1]

where LA, WD, and LD are as already described above, S1 indicates the distance, in the direction of the length LD or LA, between the light-emitting devices 300, and S2 indicates the distance, in the direction of the width WD, between the light-emitting devices 300. As the light-emitting devices 300 extend in one direction and the height HD of the light-emitting devices 300 is greater than the lengths LD and LA of the light-emitting devices 300, the size of the active layers 330 may increase, and the area of the active layers 330 per unit area may also increase.

As described above, each of the light-emitting devices 300 may include a body part BP and a light-emitting part AP, and the light-emitting part AP may protrude from the body part BP. In a case where the direction faced by the light-emitting parts AP of the light-emitting devices 300 with respect to the body parts BP of the light-emitting devices 300 is referred to as an alignment direction, the light-emitting devices 300, which are disposed between first and second electrode lines 210A and 210B, may be classified according to their alignment direction.

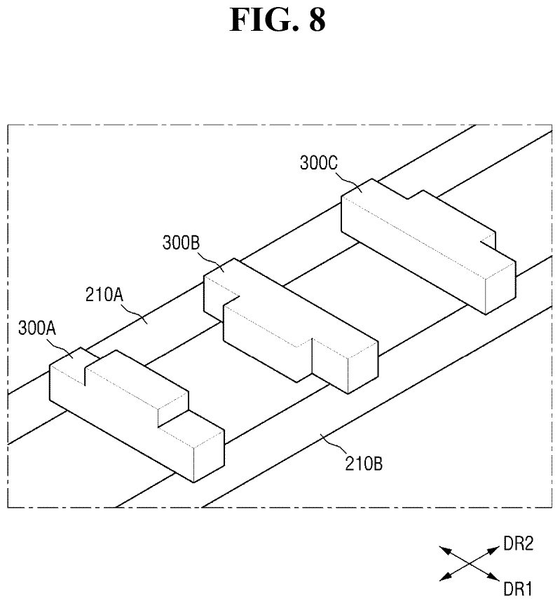

FIG. 8 is a perspective view illustrating the alignment directions of light-emitting devices according to one or more embodiments of the present disclosure.

Referring to FIG. 8, a display device 10 may include light-emitting devices (300A, 300B, and 300C), which differ from one another in the direction faced by third end portions or light-emitting parts AP of light-emitting devices 300. The light-emitting devices 300 may include a first light-emitting device 300A whose light-emitting part AP faces an upward direction of a first substrate 100 and second and third light-emitting devices 300B and 300C whose light-emitting parts AP face a second direction DR2. The second and third light-emitting devices 300B and 300C may be disposed to have their light-emitting parts AP face a direction parallel to the direction in which a first electrode 210 extends. The light-emitting part AP of the second light-emitting device 300B may be aligned in one direction in the second direction DR2, and the light-emitting part AP of the third light-emitting device 300C may be aligned in the other direction in the second direction DR2.

During the fabrication of the display device 10, the light-emitting devices 300 may be sprayed onto the first electrode 210 in a state of being dispersed in the ink. In response to alignment signals being applied to first and second electrode lines 210A and 210B, an electric field may be generated on the first electrode 210 (e.g., an electric field may be generated between the first and second electrode lines 210A and 210B). The light-emitting devices 300 dispersed in the ink may receive a dielectrophoretic force from the electric field and may thus be arranged between the first and second electrode lines 210A and 210B with their positions and alignment directions continuously changing. Each of the light-emitting devices 300 may include a body part BP having a large length LD and a light-emitting part AP having relatively a shorter length (LA) than the body part BP, and the light-emitting parts AP of the light-emitting devices 300 may have different alignment directions. As is clear from the first, second, and third light-emitting devices 300A, 300B, and 300C, the body parts BP, which account for large parts of the light-emitting devices 300, may be disposed directly on the first and second electrode lines 210A and 210B. As the light-emitting parts AP of the light-emitting devices 300 are disposed to face the second direction DR2 or the upward direction of the first substrate 101, light generated by the active layers 330 of the light-emitting devices 300 may be emitted in various directions.

First and second end portions of each of the body parts of the first, second, and third light-emitting devices 300A, 300B, and 300C may be disposed on the first electrode 210 and may be in contact with the first electrode 210 at different locations. The bottom surfaces of the first and second end portions of the first light-emitting device 300A, particularly, a sub-semiconductor layer 390 of the light-emitting device 300, may be disposed directly on the first and second electrode lines 210A and 210B. On the contrary, surfaces of the first and second end portions of each of the second and third light-emitting devices 300B and 300C, particularly, insulating films 380 of the light-emitting devices 300, may be disposed directly on the first and second electrode lines 210A and 210B.

As first semiconductor layers 310 of the light-emitting devices are exposed in the first and second end portions of each of the light-emitting devices 300, a first contact electrode 261, which is disposed on the first and second end portions of each of the light-emitting devices 300 and the first electrode 210, may be in direct contact with the exposed first semiconductor layers 310 on the sides of the first and second end portions of each of the light-emitting devices 300. The first contact electrode 261 may be disposed to extend in the second direction DR2 and may be around (e.g., may surround) the first and second end portions of each of the light-emitting devices 300. Accordingly, the first contact electrode 261 may be in direct contact with the top surfaces and sides of the first semiconductor layers 310 exposed in the first and second end portions of each of the light-emitting devices 300.

Also, a distance DC between first and second patterns 261A and 261B of the first contact electrode 261 may be less than a distance DE between the first and second electrode lines 210A and 210B. As the first contact electrode 261 is disposed to be around (e.g., to surround) the first and second end portions of each of the light-emitting devices 300, at least part of the first contact electrode 261 may be disposed directly on a first planarization layer 109. However, as the distance DC between the first and second patterns 261A and 261B is greater than a length LA of the light-emitting parts AP of the light-emitting devices 300, the first and second patterns 261A and 261B may not be in contact with the light-emitting parts AP of the light-emitting devices 300.

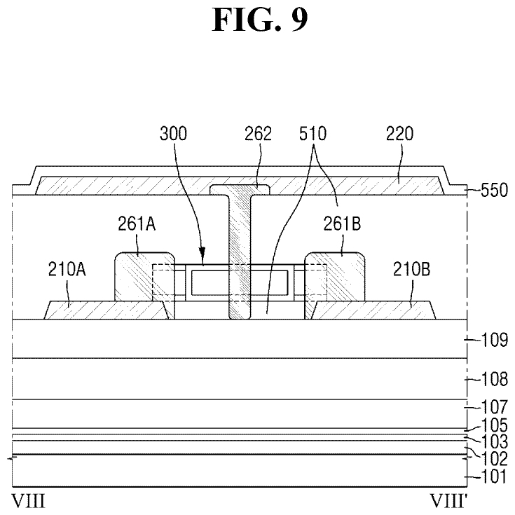

FIG. 9 is a cross-sectional view taken along the line VIII-VIII′ of FIG. 2. FIG. 9 illustrates the layout of first and second contact electrodes 261 and 262 relative to a second or third light-emitting device 300B or 300C.

Referring to FIG. 9 and further to FIG. 3, first and second end portions of a light-emitting device 300 may be in contact with first and second patterns 261A and 261B, respectively, of the first contact electrode 261. A first semiconductor layer 310 may be exposed on the top surface and sides of each of the first and second end portions, and the first and second patterns 261A and 261B may be in direct contact with the exposed first semiconductor layer 310.

Here, as the first contact electrode 261 is disposed to extend in the second direction DR2, the first contact electrode 261 may be in contact with both the top surface and sides of the exposed first semiconductor layer 310, regardless of the alignment direction of the light-emitting device 300, which is disposed between first and second electrode lines 210A and 210B. In a case where the light-emitting device 300 is a first light-emitting device 300A, as illustrated in FIG. 3, a surface of the first contact electrode 261 that is in contact with the top surface of the exposed first semiconductor layer 310, among surfaces of the first contact electrode 261 that are in contact with the first and second end portions of the light-emitting device 300, may be parallel to the top surface of the first substrate 101. On the contrary, in a case where the light-emitting device 300 is a second or third light-emitting device 300B or 300C, as illustrated in FIG. 8, the surface of the first contact electrode 261 that is in contact with the top surface of the exposed first semiconductor layer 310, among the surfaces of the first contact electrode 261 that are in contact with the first and second end portions of the light-emitting device 300, may be perpendicular to the top surface of the first substrate 101. In one or more embodiments, surfaces of the first contact electrode 261 that are in contact with sides of the first and second end portions of each of the first, second, and third light-emitting devices 300A, 300B, and 300C may be formed to be perpendicular to the top surface of the first substrate 101.

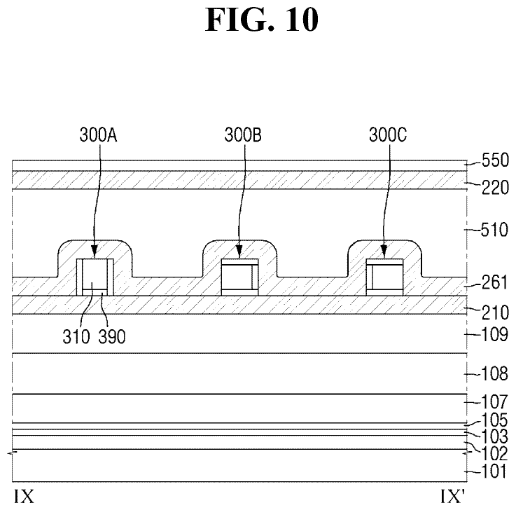

FIG. 10 is a cross-sectional view taken along the line IX-IX' of FIG. 2. FIG. 10 illustrates first and second end portions of each of first, second, and third light-emitting devices 300A, 300B, and 300C that are in contact with a first contact electrode 261, particularly, sides of a first semiconductor layer 310 and sides of a sub-semiconductor layer 390 in each of the first, second, and third light-emitting devices 300A, 300B, and 300C.

Referring to FIG. 10 and further to FIGS. 3 and 9, at least one of the first and second end portions of each of the first, second, and third light-emitting devices 300A, 300B, and 300C may be surrounded by the first contact electrode 261. The first contact electrode 261 may be in contact not only with an exposed first semiconductor layer 310, but also with an insulating film 380. The contact surface of the first contact electrode 261 and the first semiconductor layer 310 exposed in the first and second end portions of each of the light-emitting devices 300 may increase. As a result, the contact resistance between the first contact electrode 261 and the first semiconductor layer 310 may decrease.

Similarly, a second contact electrode 262 may be disposed to be around (e.g., to surround) not only third end portions, but also parts of light-emitting parts AP and body parts BP of the light-emitting devices 300.

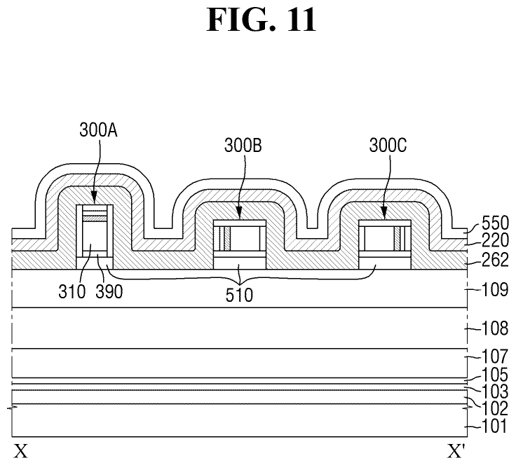

FIG. 11 is a cross-sectional view taken along the line X-X′ of FIG. 2. FIG. 11 illustrates third end portions of first, second, and third light-emitting devices 300A, 300B, and 300C that a second contact electrode 262 is in contact with.

Referring to FIG. 11 and further to FIGS. 3 and 9, the first insulating layer 510 may include holes (“HP” of FIG. 3), which expose parts of the third end portions of the light-emitting devices 300, and the second contact electrode 262 may be in contact with the third end portions of the light-emitting devices 300 through the holes HP. However, the holes HP of the first insulating layer 510 may extend in the second direction DR2 to expose parts of the middle portions of the light-emitting devices 300.

In the case of the first light-emitting device 300A, not only the top surface of the third end portion of the light-emitting device 300, i.e., the top surface of an electrode layer 370, but also first and second surfaces of the light-emitting device 300 may be exposed by the holes HP of the first insulating layer 510. In the case of the second and third light-emitting devices 300B and 300C, not only the top surface of an electrode layers 370 of each of the light-emitting devices 300, but also a first or second surface and the bottom surface of each of the light-emitting devices 300 may be exposed by the holes HP of the first insulating layer 510. As the second contact electrode 262 is disposed in the holes HP and extends in the second direction DR2, the second contact electrode 262 may be around (e.g., may surround) parts of the first, second, and third light-emitting devices 300A, 300B, and 300C.

In one or more embodiments, the second contact electrode 262 may be in contact not only with the light-emitting parts AP or the third end portions of the light-emitting devices 300, but also with portions of body parts BP of the light-emitting devices 300 that are directly connected to light-emitting parts AP of the light-emitting devices 300. The portions of the body parts BP that the second contact electrode 262 is in contact with may be portions of the body parts BP where an insulating film 380 is disposed, particularly, first and second surfaces, in the direction of the width WD, of each of the body parts BP, and may be the bottom surface of the sub-semiconductor layer 390. For example, in one or more embodiments, in the case of the first light-emitting device 300A, not only the top surface of the electrode layer 370 of the first light-emitting device 300A, but also the first and second surfaces, in the direction of the width WD, of the body part BP of the first light-emitting device 300A and the bottom surface of the sub-semiconductor layer 390 of the first light-emitting device 300A may be in contact with the second contact electrode 262. On the contrary, in one or more embodiments, not only the top surfaces of the electrode layers 370 of the second and third light-emitting devices 300B and 300C, but also first and second surfaces, in the direction of the width WD, of each of the body parts BP of each of the second and third light-emitting devices 300B and 300C and the bottom surfaces of the sub-semiconductor layers 390 of the second and third light-emitting devices 300B and 300C may be in contact with the second contact electrode 262.

The second contact electrode 262, which is in contact with the body parts BP, may be in direct contact with the insulating film 380 or the sub-semiconductor layer 390 in each of the body parts BP, but not with a first semiconductor layer 310. The first, second, and third light-emitting devices 300A, 300B, and 300C have different heights from the top surface of the first planarization layer 109 depending on the alignment direction of the light-emitting parts AP and thus form height differences, and as the second contact electrode 262 is disposed to have a uniform thickness along the height differences, the height from the first planarization layer 109 to the top surface of the second contact electrode 262 may vary.

The second contact electrode 262 may be in direct contact with the third end portions of the light-emitting devices 300, exposed by the holes HP, particularly, with the top surface of an exposed electrode layer 370. Also, the second contact electrode 262 may be in direct contact with the insulating film 380 and the sub-semiconductor layer 390 of each of the light-emitting devices 300. The second contact electrode 262 may not be in direct contact with a first contact electrode 261 due to the presence of the first insulating layer 510, and any short circuit between the first and second contact electrodes 261 and 262 may be prevented.

The light-emitting devices 300 may include body parts BP and light-emitting parts AP having a different length from the body parts BP and may protrude at least in part. The active layers 330 included in the light-emitting parts AP may have a relatively large area, and the emission efficiency of the light-emitting devices 300 can be improved. Also, the display device 10 may include light-emitting devices 300 whose layout varies depending on the direction faced by the light-emitting parts AP. The first and second contact electrodes 261 and 262 may extend along the direction in which the light-emitting devices 300 are arranged, and may have a large contact area with the semiconductor layers of each of the light-emitting devices 300, regardless of the alignment direction of the light-emitting devices 300. As a result, the contact resistance between the contact electrodes (261 and 262) and the light-emitting devices 300 can be reduced.

Various embodiments of a light-emitting devices 300 and a display device 10 will hereinafter be described.

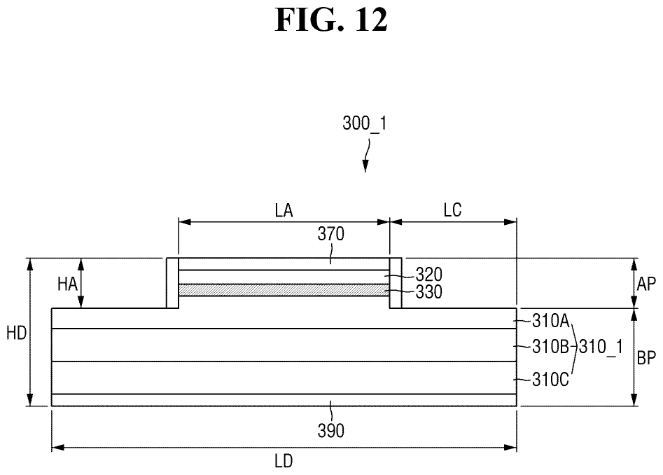

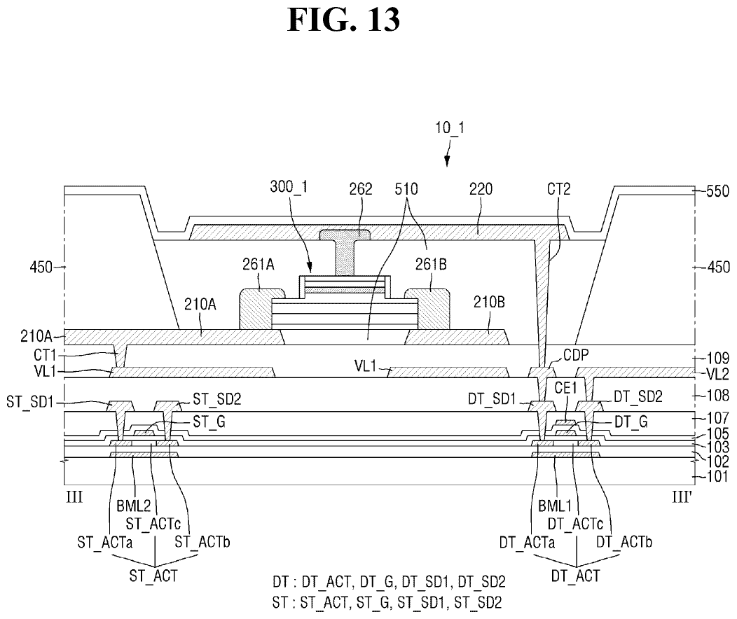

FIG. 12 is a cross-sectional view of a light-emitting device according to one or more embodiments of the present disclosure. FIG. 13 is a cross-sectional view of a display device including the light-emitting device of FIG. 12.

Referring to FIGS. 12 and 13, a first semiconductor layer 310_1 of a light-emitting device 300_1 may include a plurality of layers. The first semiconductor layer 310_1 may include first, second, and third layers 310A, 310B, and 310C, and the first, second, and third layers 310A, 310B, and 310C may be sequentially arranged along the direction in which semiconductor layers are stacked. The light-emitting device 300_1 and a display device 10_1 of FIGS. 12 and 13 differ from their respective counterparts of FIGS. 3 and 5 in that the first semiconductor layer 310_1 includes a plurality of layers. The embodiment of FIGS. 12 and 13 will hereinafter be described, focusing mainly on the differences with the embodiment of FIGS. 3 and 5.

The first semiconductor layer 310_1 of the light-emitting device 300_1 may be doped with an n-type dopant into an n-type semiconductor layer. The first semiconductor layer 310_1 may include a plurality of layers having different n-type dopant doping concentrations or carrier concentrations, for example, the first, second, and third layers 310A, 310B, and 310C. The first layer 310A may be disposed on a first portion of the first semiconductor layer 310_1, which corresponds to a body part BP of a light-emitting device 300, and part of the top surface of the first layer 310A, which corresponds to the first portion of the first semiconductor layer 310_1, may protrude to form a second portion of the first semiconductor layer 310_1. An active layer 330 may be disposed on a protruding part of the first layer 310A. The second and third layers 310B and 310C may be disposed on the first portion of the first semiconductor layer 310_1.

In one or more embodiments, the carrier concentration of the first semiconductor layer 310_1 may gradually decrease from the first layer 310A to the third layer 310C. That is, the carrier concentration of the third layer 310C may be lower than the carrier concentrations of the first and second layers 310A and 310B, and the carrier concentration of the second layer 310B may be lower than the carrier concentration of the first layer 310A. However, the present disclosure is not limited thereto. The higher the carrier concentration of the first semiconductor layer 310_1, the lower the resistance of the first semiconductor layer 310_1. As the first semiconductor layer 310_1 includes a plurality of layers (310A, 310B, and 310B), the carrier concentration of the light-emitting device 300_1 may increase from a sub-semiconductor layer 390 to the active layer 330, and the resistance of the light-emitting device 300_1 may decrease from the sub-semiconductor layer 390 to the active layer 330. The device efficiency of the light-emitting device 300_1 can be further improved.

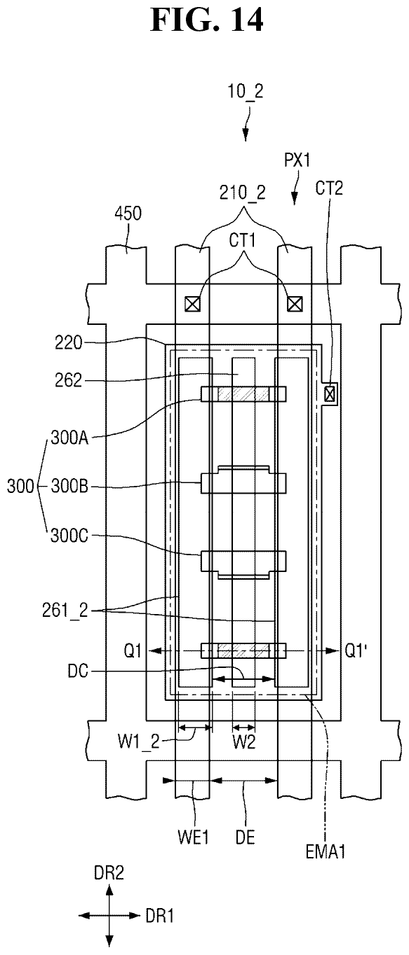

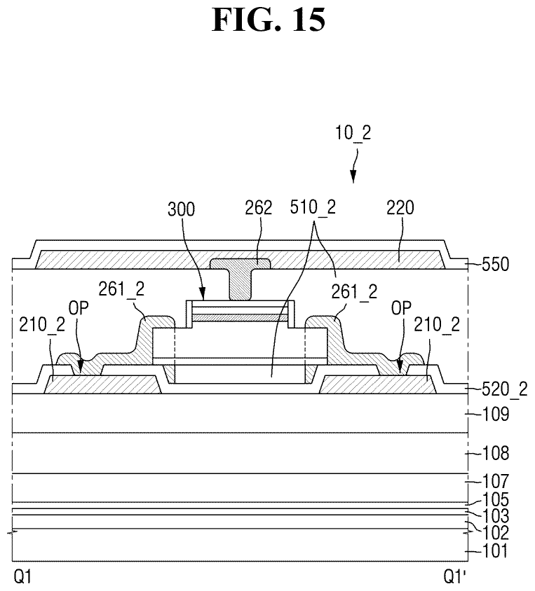

FIG. 14 is a plan view of a subpixel of a display device according to one or more embodiments of the present disclosure. FIG. 15 is a cross-sectional view taken along the line Q1-Q1′ of FIG. 14.

Referring to FIGS. 14 and 15, a display device 10_2 may include a first electrode 210_2 and a second insulating layer 520_2, which is disposed on the entire surface of a first planarization layer 109. A first contact electrode 261_2 may be disposed directly on the second insulating layer 520_2 and may be in direct contact with the first electrode 210_2, which is exposed by openings OP, which are formed in the second insulating layer 520_2. The display device 10_2 of FIGS. 14 and 15 differs from its counterpart of FIGS. 2 and 3 in that it further includes the second insulating layer 520_2. The embodiment of FIGS. 14 and 15 will hereinafter be described, focusing mainly on the differences with the embodiment of FIGS. 2 and 3.

The display device 10_2 may further include the second insulating layer 520_2, which is disposed to cover the first electrode 210_2. The second insulating layer 520_2 may include substantially the same material as a first insulating layer 510_2 and may thus form another layer disposed to cover the first electrode 210_2 and the first planarization layer 109. As the second insulating layer 520_2 is disposed to cover the first electrode 210_2, light-emitting devices 300 may be disposed directly on the second insulating layer 520_2. The second insulating layer 520_2 can prevent the light-emitting devices 300 from being in direct contact with the second insulating layer 520_2, and an electrical signal applied to the first electrode 210_2 can be transmitted to the light-emitting devices 300 through a first contact electrode 261_2.

The openings OP, which expose parts of the top surface of the first electrode 210_2 through the second insulating layer 520_2, may be formed in the second insulating layer 520_2. The openings OP may be formed in areas overlapping with first and second electrode lines 210A and 210B. In one or more embodiments, the openings OP may extend in a second direction DR2. The openings OP may be formed to be at a suitable distance (e.g., a predetermined distance) from the light-emitting devices 300, and the first contact electrode 261_2 may be formed to have a larger width than the openings OP, i.e., a width W1_2, and thus to cover the openings OP. As the width W1_2 of the first contact electrode 261_2 is greater than the width of the first contact electrode 261 of FIG. 2, the width W1_2 of the first contact electrode 261_2 may differ from a width W2 of a second contact electrode 262. For example, the width W1_2 of the first contact electrode 261_2 may be greater than the width W2 of the second contact electrode 262. The first contact electrode 261_2 may have a relatively large width, i.e., the width W1_2, and may cover the openings OP while maintaining a distance DC between first and second patterns 261A and 261B. The first and second patterns 261A and 261B may be in contact with the first and second electrode lines 210A and 210B, respectively, exposed by the openings OP, and the light-emitting devices 300 may be electrically connected to the first electrode 210_2 through the first and second patterns 261A and 261B.

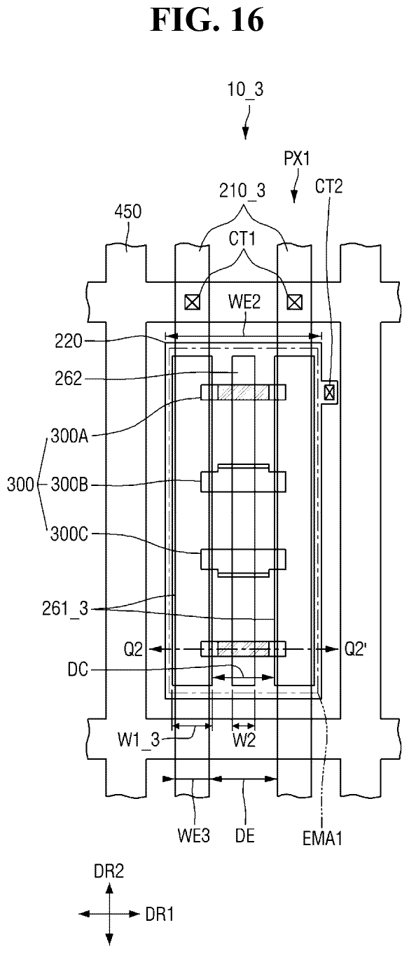

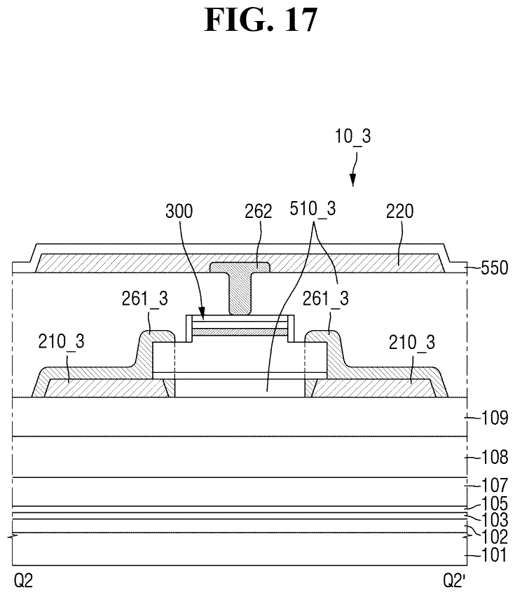

FIG. 16 is a plan view of a subpixel of a display device according to one or more embodiments of the present disclosure. FIG. 17 is a cross-sectional view taken along the line Q2-Q2′ of FIG. 16.

Referring to a display device 10_3 of FIGS. 16 and 17, a width W1_3 of a first contact electrode 261_3 may be greater than a width WE3 of a first electrode 210_3. First and second patterns 261A and 261B of the first contact electrode 261_3 may be disposed to cover first and second electrode lines 210A and 210B, respectively. The first contact electrode 261_3 may be in contact with a relatively large area of a first electrode 210_3, and the contact resistance between the first contact electrode 261_3 and the first electrode 210_3 can be further reduced. The display device 10_3 of FIGS. 16 and 17 differs from its counterpart of FIGS. 2 and 3 in the width W1_3 of the first and second patterns 261A_3 and 261B_3, and descriptions of other features of the display device 10_3 will be omitted.

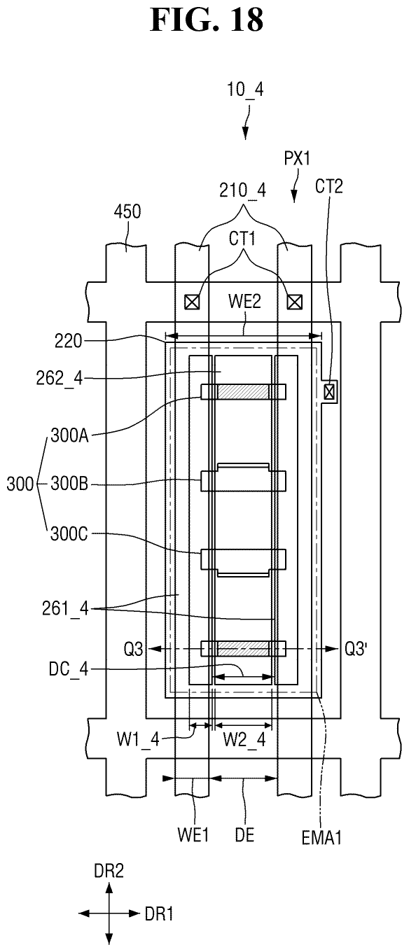

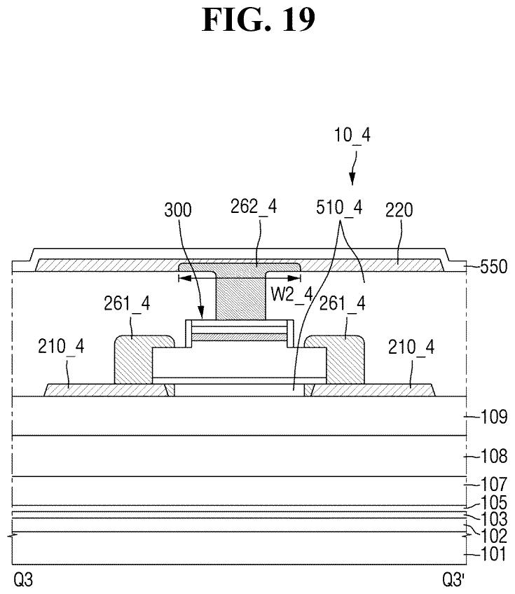

FIG. 18 is a plan view of a subpixel of a display device according to one or more embodiments of the present disclosure. FIG. 19 is a cross-sectional view taken along the line Q3-Q3′ of FIG. 18.

Referring to a display device 10_4 of FIGS. 18 and 19, a width W2_4 of a second contact electrode 262_4 of a display device 10_4 may be greater than a width W1_4 of a first contact electrode 261_4. The display device 10_4 of FIGS. 18 and 19 differs from its counterpart of FIGS. 2 and 3 in the width W2_4 of the second contact electrode 262_4. The embodiment of FIGS. 18 and 19 will hereinafter be described, focusing mainly on the differences with the embodiment of FIGS. 2 and 3.

The second contact electrode 262_4 of the display device 10_4 may be disposed in holes HP of a first insulating layer 510_4 to be around (e.g., to surround) third end portions of light-emitting devices 300. Parts of the second contact electrode 262_4 that are substantially in contact with semiconductor layers of each of the light-emitting devices 300 may be parts of a surface of the second contact electrode 262_4 that are in contact with electrode layers 370 exposed on the top surfaces of light-emitting parts AP of the light-emitting devices 300. The first contact electrode 261_4 may be in contact with the top surface and sides of each of first and second end portions of each of the light-emitting devices 300 and may thus be in contact with a relatively large area of an exposed first semiconductor layer 310 of each of the light-emitting devices 300. The second contact electrode 262_4 of the display device 10_4 may be formed to have a larger width than the first contact electrode 261_4 and may be in contact with a relatively large area of the top surface of the light-emitting part AP of each of the light-emitting devices 300, i.e., an electrode layer 370 or a second semiconductor layer 320 of each of the light-emitting devices 300. Accordingly, the contact resistance between the second contact electrode 262_4 and the light-emitting devices 300 can be further reduced.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A light emitting element comprising:
a first semiconductor layer doped with a first type dopant;
a second semiconductor layer doped with a second type dopant; and
an active layer disposed between the first semiconductor layer and the second semiconductor layer,
wherein the light emitting element includes a first portion having a first length in a first direction, and a second portion protruding from the first portion in a second direction perpendicular to the first direction and having a second length in the first direction,
wherein the second length is different from the first length, and
wherein a thickness of the light emitting element in the second direction is less than a length of the light emitting element in the first direction.

2. The light emitting element of claim 1, wherein a length of the first portion of the light emitting element in a third direction perpendicular to the first direction and the second direction is same as a length of the second portion of the light emitting element in the third direction.

3. The light emitting element of claim 1, wherein the second length of the second portion of the light emitting element is less than the first length of the first portion of the light emitting element.

4. The light emitting element of claim 1, wherein the first semiconductor layer includes a first sub portion having a first length measured in the first direction and a second sub portion having a second length measured in the first direction different from the first length of the first sub portion of the first semiconductor layer,
wherein the first portion of the light emitting element includes the first sub portion of the first semiconductor layer, and
wherein the second portion of the light emitting element includes the second sub portion of the first semiconductor layer.

5. The light emitting element of claim 4, wherein the active layer has a third length measured in the first direction,
wherein the third length of the active layer is same as the second length of the second sub portion of the first semiconductor layer.

6. The light emitting element of claim 5, wherein the second sub portion of the first semiconductor layer is disposed between the active layer and the first sub portion of the first semiconductor layer.

7. The light emitting element of claim 4, wherein the second sub portion of the first semiconductor layer is disposed on the first sub portion of the first semiconductor layer in the second direction.

8. The light emitting element of claim 4, wherein a thickness of the second sub portion of the first semiconductor layer in the second direction is different from a thickness of the first sub portion of the first semiconductor layer in the second direction.

9. The light emitting element of claim 8, wherein the thickness of the second sub portion of the first semiconductor layer in the second direction is less than the thickness of the first sub portion of the first semiconductor layer in the second direction.

10. The light emitting element of claim 1, wherein a thickness of the first semiconductor layer in the second direction is greater than a thickness of the second semiconductor layer in the second direction.

11. The light emitting element of claim 1, further comprising an insulating film disposed on a side surface of the first portion of the light emitting element.

12. The light emitting element of claim 11, wherein the insulating film surrounds a side surface of at least portion of the first semiconductor layer, a side surface of the second semiconductor layer, and a side surface of the active layer.

13. The light emitting element of claim 11, further comprising an electrode layer disposed on the second semiconductor layer,
wherein the insulating film surrounds a side surface of the electrode layer.

14. The light emitting element of claim 13, wherein the electrode layer comprises at least one of aluminum (AI), titanium (Ti), indium (In), gold (Au), silver (Ag), indium tin oxide (ITO), indium zinc oxide (IZO), and indium tin-zinc oxide (ITZO).

15. The light emitting element of claim 1, wherein a shape of the light emitting element in plan view is a rectangular shape.

16. The light emitting element of claim 1, further comprising a sub semiconductor layer which overlaps the first semiconductor layer.
